(19) United States
(12) Patent Application Publication
(10) Pub. No.: US 2007/0290901 A1
(43) Pub. Date: Dec. 20, 2007

(54) Encoding and Decoding Apparatus and Corresponding Methods

(75) Inventors: Andries Pieter Hekstra, Eindhoven (NL); Ludovicus Marinus Gerardus Maria Tolhuizen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics, N.V., Eindhoven (NL)

(21) Appl. No.: 11/569,764

(22) PCT Filed: May 26, 2005
(86) PCT No.: PCT/IB05/51730

§ 371 Date: Aug. 1, 2007

(30) Foreign Application Priority Data
Jun. 2, 2004 (EP) 04102459.7

(51) Int. Cl. H03M 7/00; H03M 13/00

(52) U.S. Cl. 341/95; 341/94

(57) ABSTRACT

The present invention relates to an encoding apparatus and method for encoding a user data stream (m) into a channel data stream (y) as well as to a corresponding decoding apparatus and method. To improve the worst case BER behavior of storage systems and increase reliability, in particular which ensure a low BER without a large loss of information rate, particularly in two-dimensional optical storage systems or in communication systems, an encoding apparatus is proposed according to the invention which comprises: an expansion unit for transforming said user data stream (m) to an intermediate data stream (i) comprising at least one more symbol than said user data stream (m), a processing unit (100, 200, 500, 600) for iteratively determining for each scrambling stream (c) from a scrambling code (C) the value (v) of a figure of merit for the scrambling stream (c) using said intermediate data stream (i), a selection unit (300) for selecting an optimum merit value (v_opt) from said merit values (v) and for selecting an optimum scrambling stream (copt) for which the figure of merit equals said optimum merit value (v_opt), and at least one mapping unit (400) for mapping the symbols of said optimum scrambling stream (copt) onto the corresponding symbols of said intermediate data stream (i) to obtain said channel data stream (y) for output to a channel.

The present invention relates to an encoding apparatus and method for encoding a user data stream into a channel data stream. The invention relates further to a corresponding decoding apparatus and method, to a record carrier and a signal carrying data encoded according to the invention and to a computer program for implementing said methods.

A system for two-dimensional optical storage, in particular a method of encoding and decoding a two-dimensional channel data stream, is described in European patent application EP 02076665.5 (PHNL 020368). The aim of two-dimensional optical storage is to achieve a higher storage density, e.g. 2.0 times larger than Blu-Ray Disc (BD), using the same physical read-out system (wavelength, numerical aperture). One ingredient of the envisioned two-dimensional optical storage system is to use a two-dimensional hexagonal lattice for the bit (multi-level symbol) cells on the optical media. Thus, each bit (symbol) has six nearest neighbors. In a first shell approximation involving only the nearest neighbor bits, the channel output when the readout spot is above a certain input bit xᵢ with two-dimensional index i is a function of this input bit and the number of its six nearest neighbor bits that are equal to one. This number is called zᵢ.

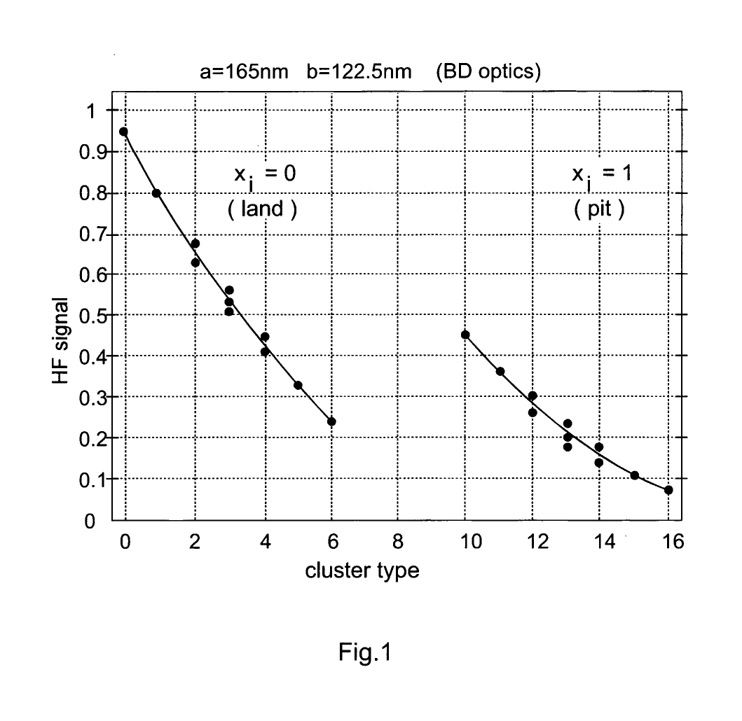

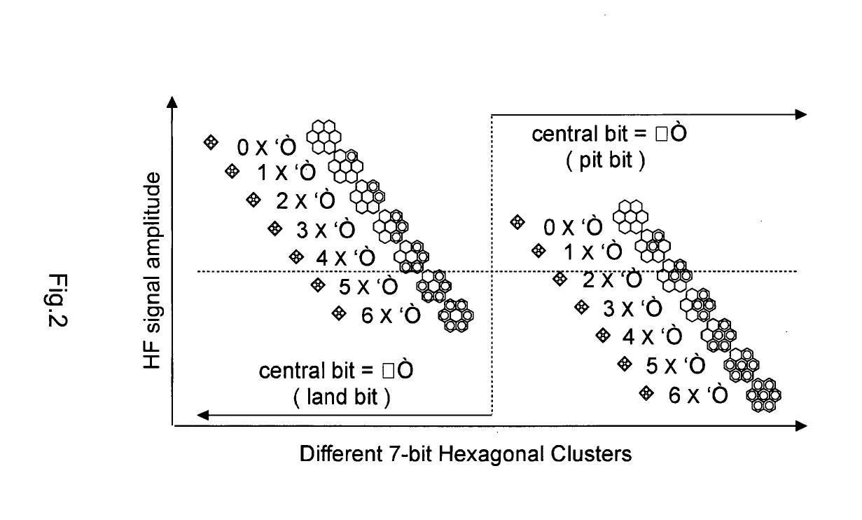

FIG. 1 shows the first shell approximation of the channel output as a function of 10xᵢ+zᵢ. Thus, the situation with a zero bit surrounded by six zero bits corresponds to the left most point of the curve in the figure. Similarly, the situation with a one bit surrounded by six one bits corresponds to the right most point of the curve. In FIG. 2 the different cluster types of 7-bit hexagonal clusters are shown.

The Bit Error Rate (BER) depends on the sequence (two-dimensional lattice) of channel inputs x, which is called the channel input field, and is worst when the channel input field consists of all ones. Then, the (average) bit error rate (BER), is much worse than for a typical random input message. If an Additive White Gaussian Noise (AWGN) channel model is used, the worst case of the BER over all input fields is determined by the minimum squared Euclidean distance between two different (noiseless) channel output fields.

It has been shown that, for two-dimensional optical storage for storage densities exceeding those of one-dimensional optical storage while using the same read out physics, the minimum squared Euclidean distance between different channel output fields occurs for a pair of channel input fields where the six nearest neighbor bits are all ones, and the center bit is either zero or one and all bits further out are all ones. This fact can be heuristically explained by the fact that the (square of) the vertical distance between the z-th and 10+z-th point, z=0, 1, . . . , 6 on the curve in FIG. 1 is minimal for z=6. More accurately, this (squared) difference does not tell the full story because, not just the (squared) difference in channel output above the central bit position (index) (either being zero or one—this gives rise to the differences) but also the 6 (squared) differences in channel output above the nearest neighbor bits of the central bit contribute to the total squared Euclidean distance. E.g. for z=6, the latter 6 smaller contributions each correspond to the (squared) difference between the 2nd and 3rd point on the curve of FIG. 1.

The total squared (Euclidean) distance between the channel output fields that correspond to clusters (of channel inputs) with opposite central bit is a measure of the reliability with which the central bit can be discriminated using a channel with Additive White Gaussian Noise (AWGN). (The aforementioned clusters may differ in more indices than just the central bit.) For channels with different noise behavior, different distance or discrimination measures can be defined.

In order to prevent a situation that two-dimensional optical storage may be unreliable for certain channel input fields, it has been considered to use constrained coding to forbid the right most points of the curve in FIG. 1 (i.e. the right most cluster type in FIG. 2). Constrained coding is the more general term of the discipline of which (d; k)-constrained coding is a special case. E.g. the situation in which a one bit is surrounded by six one bits can be forbidden. The information rate loss for such a constraint would be acceptable. However, then one is confronted with the minimum distance in the case of five out of the six nearest neighbor bits being one and the center bit being either zero or one. The squared Euclidean distance of this situation is only marginally larger than the minimum Euclidean distance we had before. This would mean, we also have to forbid the one but right most point (z=5, x=1) on the curve of FIG. 1 (i.e. the one but right most cluster type in FIG. 2). For a random input message the fraction of occurrence of z of the nearest neighbors being one is proportional to the binomial coefficient

$$( \begin{matrix}6 \\ z\end{matrix} ) = \frac{6 !}{z ! ( 6 - z ) !} .$$

As a result, forbidding

$$z = 5 , x = 1 is ( \begin{matrix}6 \\ 5\end{matrix} ) = 6$$

times more expensive than forbidding z=6, x=1. This way, (local) constrained coding significantly decreases the information rate but does not solve the data dependence of the average reliability in a fundamental way. With respect to other attempts to deviate from local constraints, it should be noted that there also exist weakly constrained codes, in which certain forbidden local patterns are allowed to occur with some low probability.

Before forbidding points on the curve of FIG. 1 (i.e. single cluster types of the different cluster types shown in FIG. 2), it should be realized that all points on this curve do occur for a typical random input message. For such a typical random message, the fraction of bits with six nearest neighbor bits equal to one is small ( 1/64). The smallness of this fraction of more error prone situations mitigates their contribution to the BER. Problems arise when this fraction is no longer small (e.g. larger than twice the typical fraction, viz. 1/32). This observation suggests to put constraints on the fractions of occurrence of clusters with a given value of z. These fractions should not deviate substantially from the truly random situation for any allowed input message field. This is a sufficient condition for the worst case of the BER over all allowed input message fields to be essentially the same as the BER averaged over random input messages. A logical stream size to measure the aforementioned fractions is e.g. the stream size of an error control code (error correction code, error detection code), the decoder of which follows the bit-detector.

It is an object of the present invention to provide an encoding apparatus and method which avoid the above described problems, improve the worst case BER behavior of storage systems and increase reliability, in particular which ensure a low BER without a large loss of information rate, particularly in two-dimensional optical storage systems or in communication systems. Further, a corresponding decoding apparatus and method shall be provided as well as a computer program for implementing said encoding and/or decoding method on a computer.

This object is achieved according to the present invention by an encoding apparatus as claimed in claim 1 comprising:

an expansion unit for transforming said user data stream to an intermediate data stream (i) comprising at least one more symbol than said user data stream,

a processing unit for iteratively determining for each scrambling stream from a scrambling code the value of a figure of merit for the scrambling stream using said intermediate data stream, a scrambling stream comprising equally many symbols as said intermediate data stream, wherein said figure of merit is a sum over a collection of portions of said scrambling stream, said portions comprising at least two symbol positions from said scrambling stream, each term of the sum being a figure of merit for said portion of the scrambling stream using the corresponding portion of said intermediate stream, and in each of said portions of the scrambling stream each possible combination of symbols occurs in equally many scrambling streams from said scrambling code,

a selection unit for selecting an optimum merit value from said merit values and for selecting an optimum scrambling stream for which the figure of merit equals said optimum merit value, and

at least one mapping unit for mapping the symbols of said optimum scrambling stream onto the corresponding symbols of said intermediate data stream to obtain said channel data stream for output to a channel.

The present invention is based on the idea to introduce a local randomiser in the encoding process. Guided scrambling is a well-known technique to randomise the input to a storage system while maximizing a certain object function (also called figure of merit). In telecommunication systems, it is a well-known practise to include scrambling or randomisation e.g. to prevent pathological spectral properties (“too peaky”) of the modulated signal, or to disperse the influence of (with a “peaky” spectrum) interference. In the optical recording field, guided scrambling as such is described in K. A. Schouhamer Immink, “Codes for Mass Data Storage Systems,” Shannon Foundation, Rotterdam, 1999, chapter 13. However, it has not been applied in practise.

According to the present invention the average predicted bit error rate can be expressed as one such object function (figure of merit), and the linearity of this object function (an average) is exploited. Is has been proven that for any input sequence, there exists a scrambling codeword in a small scrambling code, for which the predicted bit error rate is as good as for random input data. The invention can likewise be applied to make the worst case average power of a (filtering) communication system be not more (less) than its random average.

When bits are stored on a two-dimensional hexagonal lattice as in two-dimensional optical storage, the scrambling method of the invention costs 6 information bits per stream over which it is applied. Hence, with long streams, the rate loss is small, but locally the BER can still be large. Per input sequence (two-dimensional lattice), the predicted average bit error rate function for only 64 scrambling codewords needs to be evaluated. The method of the present invention can do this evaluation efficiently.

A decoding apparatus according to the invention is claimed in claim 13, which comprises:

an ECC decoding unit for decoding said channel data stream to a channel codeword of said error correction code,

a separation unit for finding an intermediate data stream and a scrambling codeword from said channel codeword such that mapping said scrambling codeword onto said intermediate data stream results in said channel codeword, and

a demapping unit for retrieving a user data stream from said intermediate data stream such that expanding said user data stream to an intermediate data stream comprising at least one more symbol than said user data stream results in said intermediate data stream.

The invention relates also to a record carrier as claimed in claim 15 storing a channel data stream (r) into which a user data stream (m) is encoded according to the encoding method as claimed in claim 1.

Corresponding encoding and decoding methods are defined in claims 12 and 14. Preferred embodiments of the invention are defined in the dependent claims. A signal encoded according to the encoding method of the invention is defined in claim 16. A computer program for implementing said methods is defined in claim 17.

According to a preferred embodiment histograms are used. The advantage of the histogram method is that it avoids the necessity to map the intermediate stream on all possible scrambling codewords and evaluate the figure of merit for all these possible choices. When there are in total a number of |C| scrambling codewords in the scrambling code C, and the codewords have a (block) length equal to K, the total complexity of evaluation of the figure of merit for all possibilities is equal to the product (|C| K). The histogram method has the advantage that the computational complexity is further reduced when the block length K is large. The histogram method scans the intermediate sequence once to produce the histograms. This has a complexity equal to K, i.e. a once the block length. Note that the complexity of manipulating the histograms is independent of the block length K, as only counts are dealt with. The numerical range of these counts is only proportional to the logarithm of K. When the block length K is very large, the latter complexity can be neglected with respect to the aforementioned complexity of scanning the intermediate sequence i to compile the histograms.

In general, a receiver needs to be informed of the choice of the scrambling codeword c that was used for a given message m in order to retrieve the message (“descramble”). According to the present invention this choice is conveyed by means of the expansion unit, that lengthens the message into the intermediate stream, and, hence, adds a form of redundancy. This redundancy can either take the form that a known symbol is concatenated with the message stream as defined in claim 10, or can take the form of an error correction encoding transformation as in claimed in claim 11.

Error correction codes are inherently redundant. The addition of either of these or other forms of redundancy to the message stream in the composition of the intermediate stream, allows the choice (uncertainty) which scrambling codeword is used during the encoding operation to be detected by a receiver. E.g. in case of claim 10, in the position (index) within the codeword where the inserted known symbol resides, one can retrieve a symbol (e.g. a byte) of the scrambling codeword by means of demapping (e.g. subtracting as defined in claim 3) the known symbol from the value of the symbol in the above mentioned position.

In many practical cases, the channel data stream can be disturbed by noise, erasures and other channel errors. In case the embodiment as claimed in claim 10 is used, if the received channel data stream (a noisy copy of the sent channel data stream) in the position of the known symbol is received in error due to the presence of channel noise, this would make the receiver conclude to an erroneous choice of the scrambling codeword. Hence, the receiver would demap (e.g. subtract when the mapping operation is an addition as defined in claim 3) the received channel data stream and this wrong choice of scrambling codeword, a gross decoding error would result, that, in general, can result in multiple symbol errors in the decoded message. Hence, an error propagation effect is observed in this case. In order to prevent such an explosion of symbol errors, it would be required to convey the choice of the scrambling codeword to the receiver in a way that is protected by error control coding (error correction coding). In general, in the presence of channel errors, it is also necessary to protect the remainder of the intermediate symbol stream i with error correction coding. When different error correction (control) schemes are used to reliably convey the choice of the scrambling codeword to the receiver, and to reliably convey the actual payload, i.e. the remainder of the intermediate symbol stream except the known symbol(s), two error correction encoders and decoders are necessary. In particular, as the choice of the scrambling codeword is a small amount of information (e.g. one byte, or one 10-bit symbol, or even fewer bits), when a separate error correction encoding would be applied to such a small amount of information, this would require an error control code with a tiny block length.

The first advantage of the embodiment as claimed in claim 11 is that it requires only a single error control encoder to protect both the payload (message) and the choice of the scrambling codeword from the scrambling code instead of two encoders (that each also need separate decoders in the receiver). Furthermore, through the use of this embodiment, the introduction of error correction codes with tiny block length is also avoided. Error correction codes with small block length inherently give a weak protection against channel errors, as e.g. there is some probability that all bits (symbols) in this small code are received in error due to channel errors. This effect can only be mitigated to a limited extend by means of spreading (interleaving) the bits of such a code by inserting them with some inter-distance in a larger (channel) stream, or by adding much larger amount of redundant bits or symbols that would be required in case the embodiment as claimed in claim 11 would be applied.

Further, the use of an integral error correction code C′, allows the receiver to retrieve a) the intermediate stream conveyed through the choice of in which of the |C′|/|C| possible cosets of the scrambling code the received codeword from C′ resides, and b) the scrambling codeword that has been used during the encoding through the choice in which of the |C| possible codewords in the given coset coincides with the decoded C′-codeword. Hence, the total amount of received information is comprised out of two parts, that can both be retrieved reliably.

The invention will now be described in more detail with reference to the drawings in which

FIG. 1 shows a schematic signal-pattern for a two-dimensional code on hexagonal lattices illustrating the different optical channel read-out (HF) signal levels,

FIG. 2 shows a schematic signal-pattern for a two-dimensional code on hexagonal lattices illustrating the different cluster types,

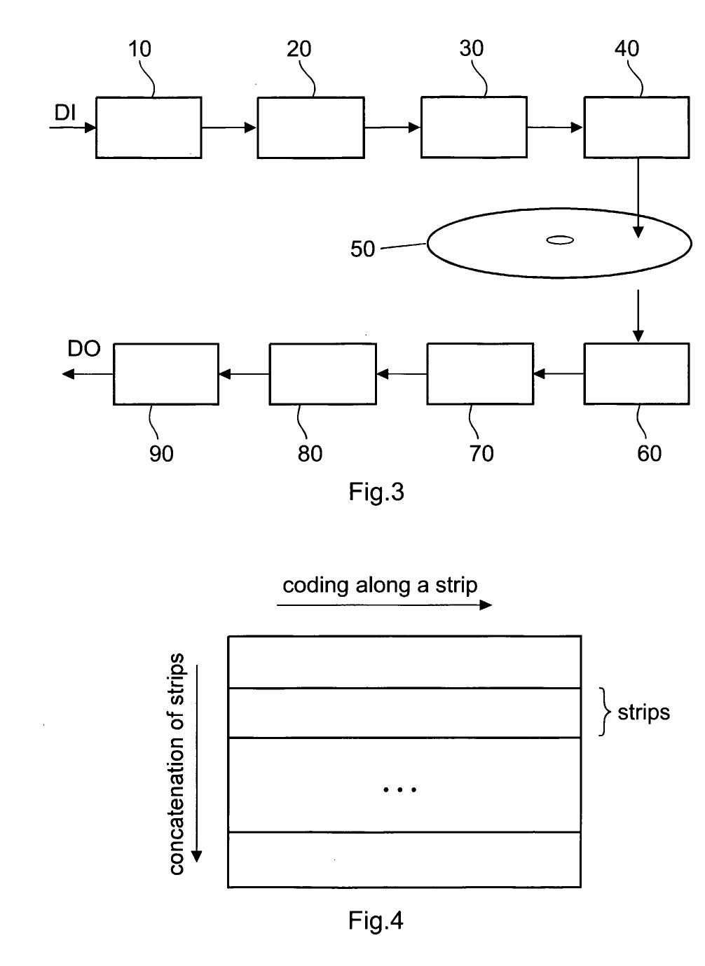

FIG. 3 shows a block diagram of a general layout of a coding system,

FIG. 4 shows a schematic diagram indicating a strip-based two-dimensional coding scheme,

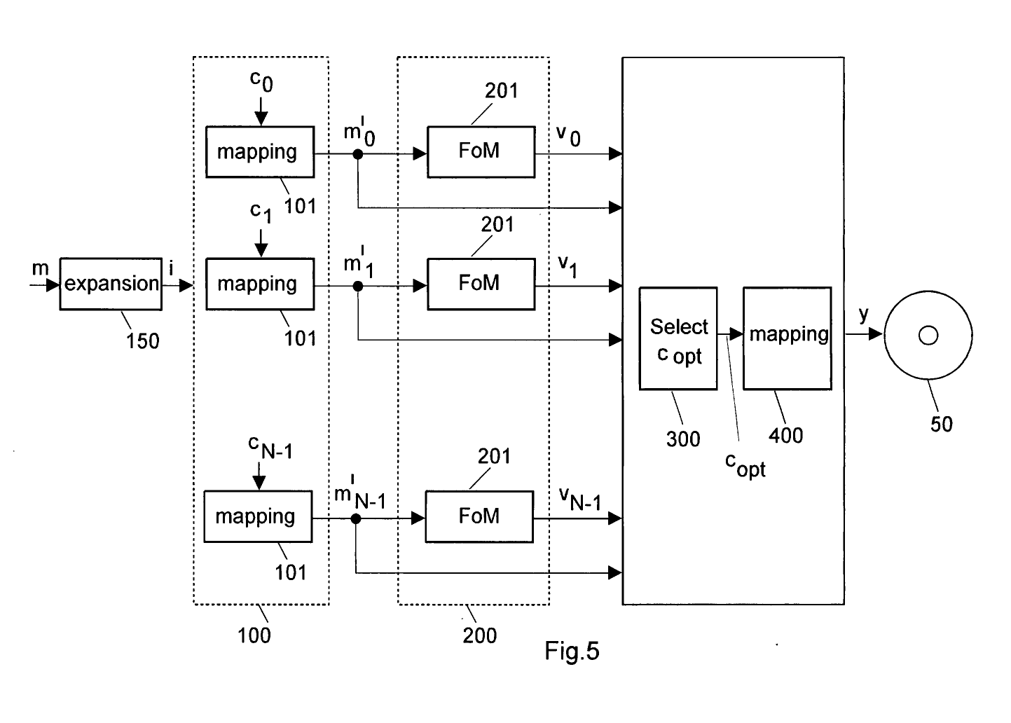

FIG. 5 show a block diagram of the general layout of an encoding apparatus according to the invention,

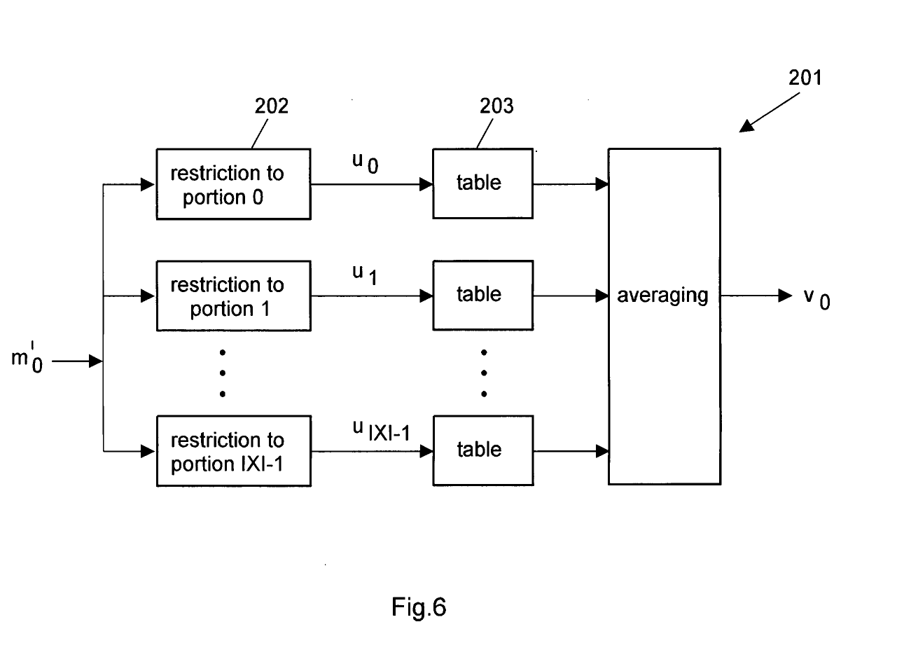

FIG. 6 shows details of the encoding apparatus shown in FIG. 5,

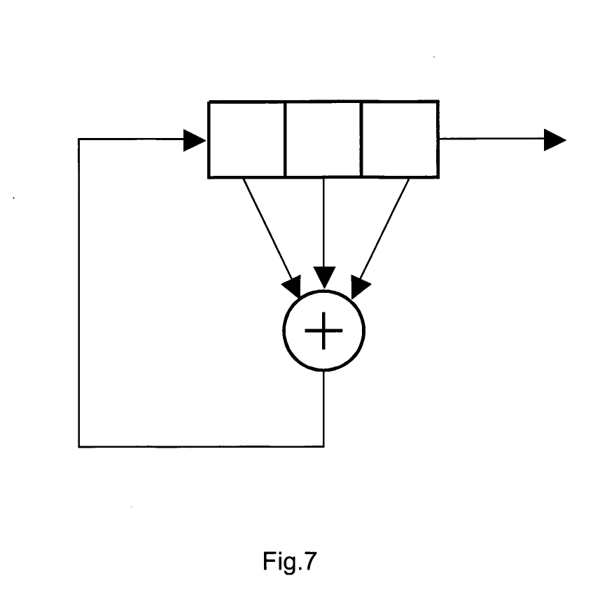

FIG. 7 shows a linear feedback shift register for generating scrambling codewords according to the invention,

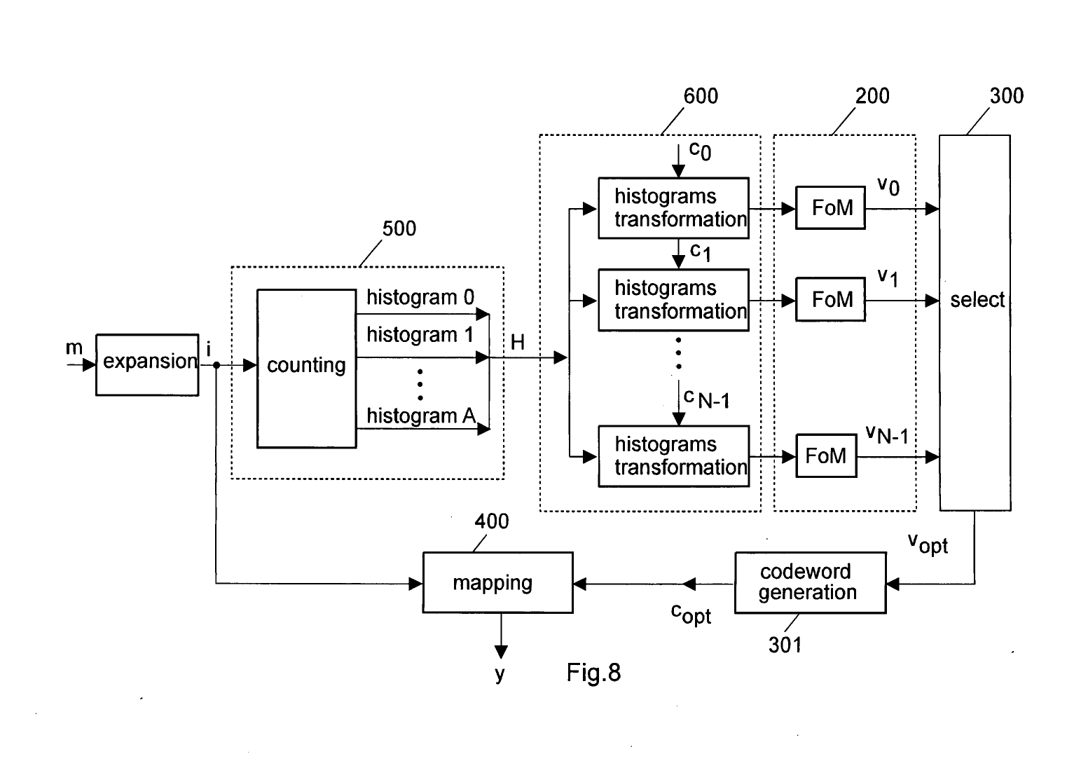

FIG. 8 show a block diagram of the an embodiment of an encoding apparatus according to the invention using histograms,

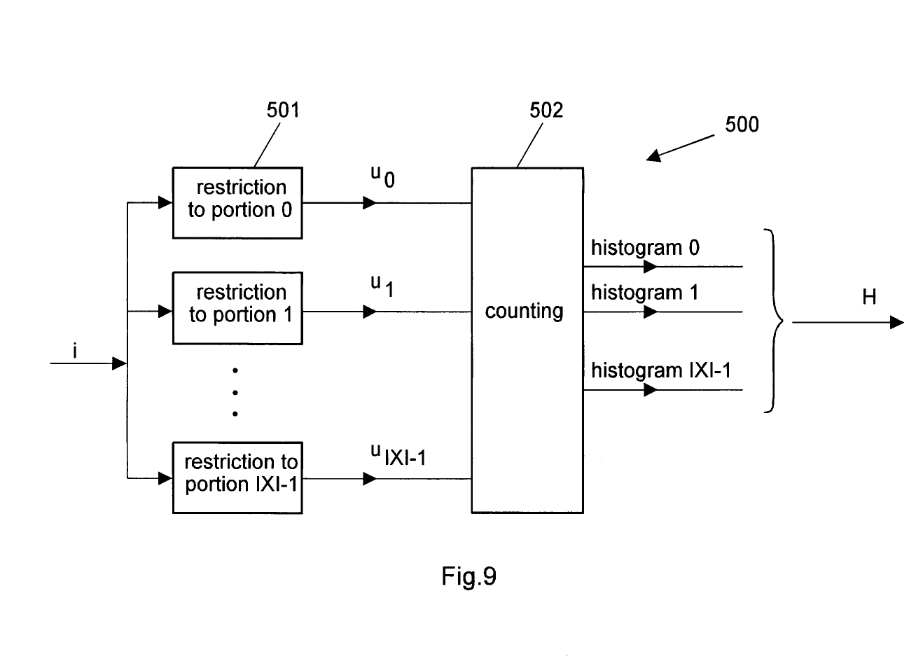

FIG. 9 shows details of the encoding apparatus shown in FIG. 8,

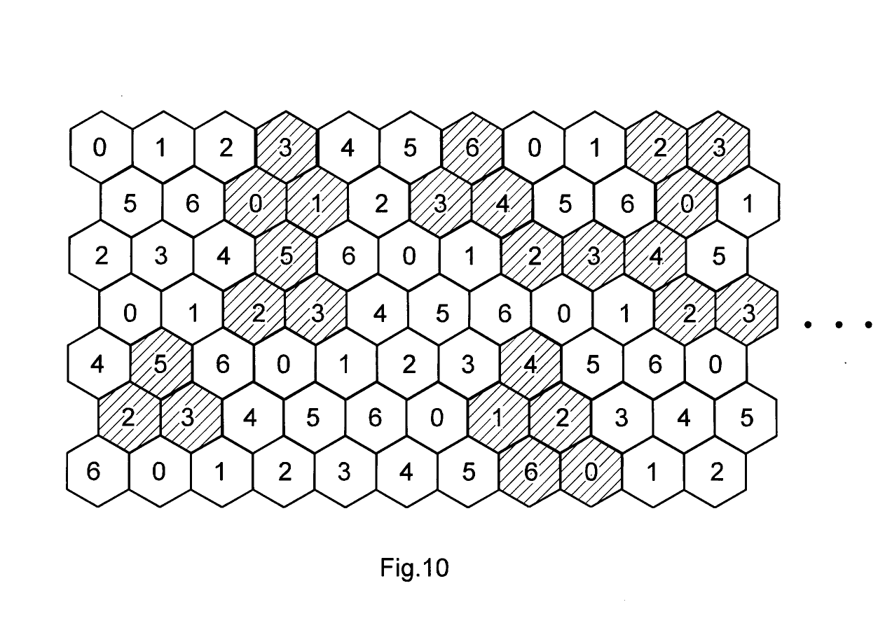

FIG. 10 shows a part of a two-dimensional channel data stream illustrating the assignment of labels to the channel symbols,

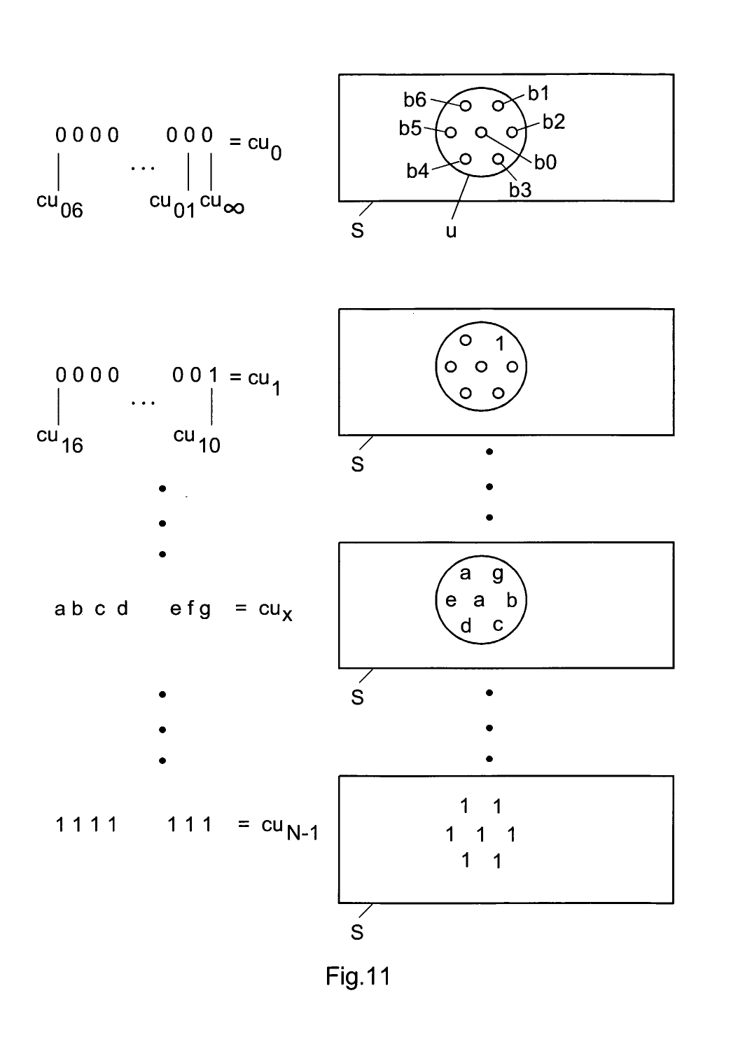

FIG. 11 illustrates the mapping of scrambling codewords onto a two-dimensional channel data stream,

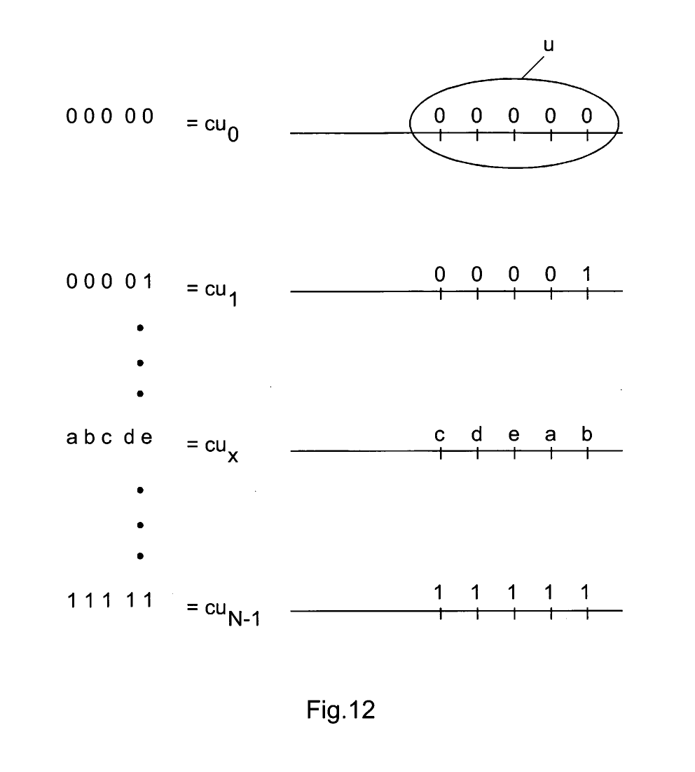

FIG. 12 illustrates the mapping of scrambling codewords onto a one-dimensional channel data stream,

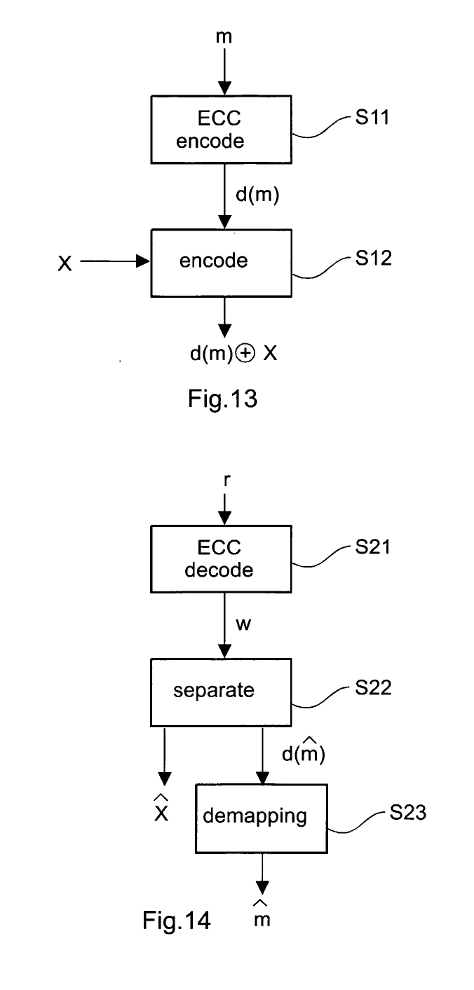

FIG. 13 shows a simple flow-chart of another embodiment of an encoding method,

FIG. 14 shows a simple flow-chart of another embodiment of a decoding method,

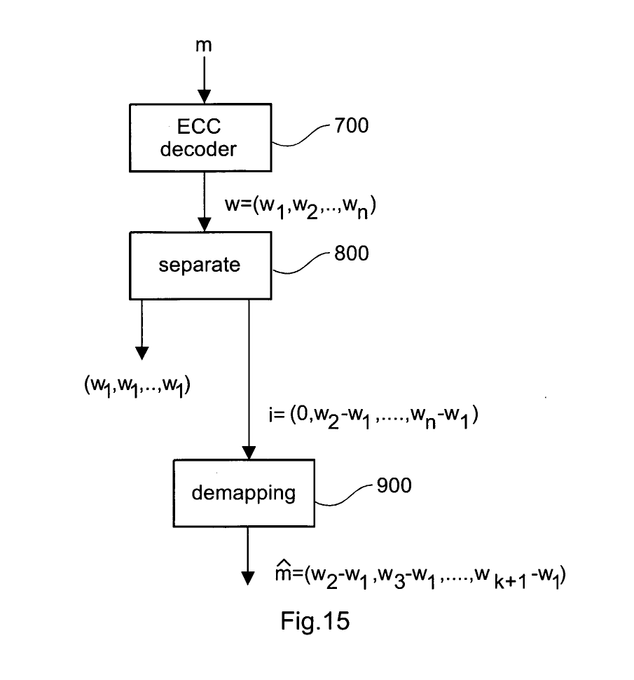

FIG. 15 shows a simple flow-chart of still another embodiment of a decoding method,

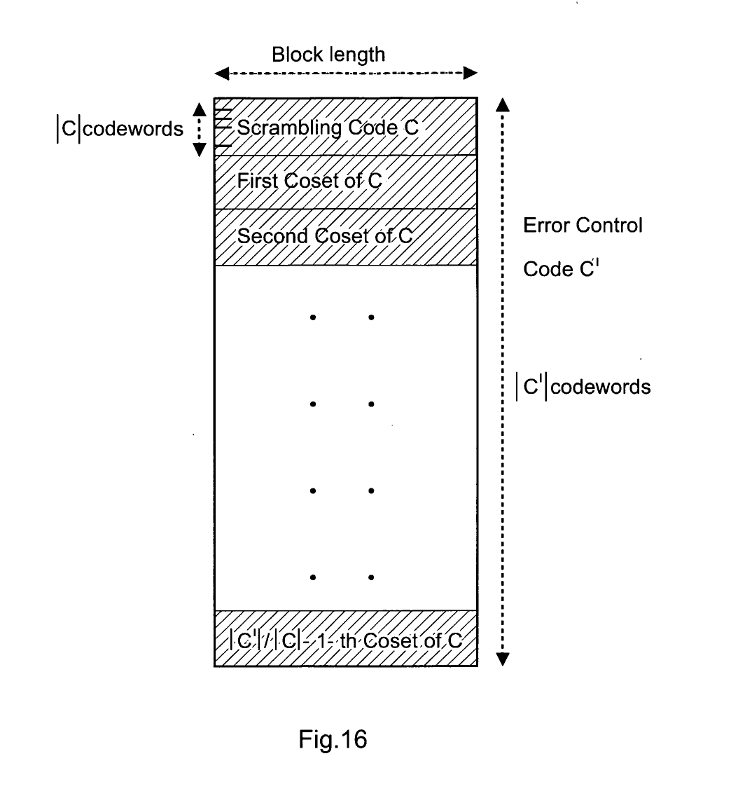

FIG. 16 shows a diagram explaining the use of the so-called lambda trick in a preferred embodiment.

FIGS. 1 and 2 show schematic signal-patterns for a two-dimensional code on hexagonal lattices illustrating the different HF signal levels (FIG. 1) and the different cluster types (FIG. 2), which have been explained above. They illustrate the problem underlying the present invention which will be avoided by the application of a guided scrambling method described in more detail below.

FIG. 3 shows typical coding and signal processing elements of a data storage system. The cycle of user data from input DI to output DO can include interleaving 10, error-control-code (ECC) and modulation encoding 20, 30, signal preprocessing 40, data storage on the recording medium 50, signal post-processing 60, binary detection 70, and decoding 80, 90 of the modulation code, and of the interleaved ECC. The ECC encoder 20 adds redundancy to the data in order to provide protection against errors from various noise sources. The ECC-encoded data are then passed on to a modulation encoder 30 which adapts the data to the channel, i.e. it manipulates the data into a form less likely to be corrupted by channel errors and more easily detected at the channel output. The modulated data are then input to a recording device, e.g. a spatial light modulator or the like, and stored in the recording medium 50. On the retrieving side, the reading device (e.g. photo-detector device or charge-coupled device (CCD)) returns pseudo-analog data values which must be transformed back into digital data (one bit per pixel for binary modulation schemes). The first step in this process is a post-processing step 60, called equalization, which attempts to undo distortions created in the recording process, still in the pseudo-analog domain. Then the array of pseudo-analog values is converted to an array of binary digital data via a bit detector 70. The array of digital data is then passed first to the modulation decoder 80, which performs the inverse operation to modulation encoding, and then to an ECC decoder 90.

By way of example, a certain two-dimensional hexagonal code shall be illustrated in the following. However, it should be noted that the general idea of the invention and all measures can be applied generally to any two-dimensional, preferably linear code, in particular any two-dimensional hexagonal or square lattice code. Finally, the general idea can also be applied to one-dimensional or multi-dimensional codes, with or without rotational symmetry of the readout channel, characterized by a one-dimensional evolution of the code.

As mentioned, in the following a two-dimensional hexagonal code shall be considered. The bits on the two-dimensional hexagonal lattice can be identified in terms of bit clusters. A hexagonal cluster consists of a bit at a central lattice site, surrounded by six nearest neighbors at the neighboring lattice sites. The code evolves along a one-dimensional direction. A two-dimensional strip consists of a number of one-dimensional rows, stacked upon each other in a second direction orthogonal to the first direction, and forming an entity over which the two-dimensional code can evolve. The principle of strip-based two-dimensional coding is shown in FIG. 4. Several strips that are coherently stacked one upon the other forms a broad two-dimensional band, which can be spiraled on an optical disc (such a band is also called a “broad-spiral”). Between successive revolutions of the broad spiral, or between neighboring two-dimensional bands a guard band of, for instance, one (empty) bit-row (filled with zero-bits, and land-marks) may be located.

The signal-levels for two-dimensional recording on hexagonal lattices are identified by a plot of amplitude values of the HF-signal for the complete set of all hexagonal clusters that are possible. Use is further made of the isotropic assumption, that is, the channel impulse response is assumed to be circularly symmetric. The latter assumption is made for reasons of simplicity of explanation is not essential for the present invention to be applicable. This implies that, in order to characterize a 7-bit cluster, it only matters to identify the central bit, and the number of “1”-bits (or “0”-bits) among the nearest-neighbor bits (0, 1, . . . , 6 out of the 6 neighbors can be a “1”-bit). A “0”-bit is a land-bit in our notation. A typical “signal-pattern” is shown in FIG. 1. Assuming a broad spiral consisting of 11 parallel bit rows, with a guard band of 1 (empty) bit row between successive broad spirals, the situation of FIG. 1 corresponds to a density increase with a factor of 1.7 compared to traditional one-dimensional optical recording (as used in e.g. in the Blu-ray Disc (BD) format (using a blue laser diode with a wavelength of 405 nm, and a lens with a numerical aperture of NA=0.85).

While the above mentioned patent application EP 02076665.5 (PHNL 020368) illustrates two-dimensional optical storage in general, the particular embodiment of the fishbone code, which is a modulation code, described therein is not applied according to the present invention. The invention preferably refers to a code which is a linear (modulo 2) subspace of the set of all binary vectors on the set of indices I, which shall be called scrambling code.

According to the present invention use is made of a guided scrambling method. A randomiser which “almost always” or “practically always” produces a typical random output sequence is easy. Almost all sequences have the characteristics of a typical uniformly random sequence, so that it would not be necessary to do something. Alternatively, a single random scrambling sequence, e.g. a maximum length shift register sequence, could be taken, and the input sequence could be added modulo q=2 with the scrambling sequence. Such scrambling systems are well known. Supposing that such a scrambling system were employed in a storage system, such as the two-dimensional optical storage system, there is always a tiny probability that (a significant part of) the input sequence of the scrambler equals the scrambling sequence or its binary complement. Then, the scrambler output sequence will be (partly) all zeroes or all ones, which is all but typically random. Then, the reliability of reading out such pathological sequences may be well below what is acceptable in the “all ones” situation as explained above. Therefore, the existence of such pathological situations is not acceptable. A storage system must meet its reliability requirements for all input sequences. This requires the provision of “guaranteed” scrambling.

According to the invention certain benefits that can be obtained by using a scrambling code C shall be exploited. Let I be a finite index set, e.g. a set of points in space or time at which bits are stored or transmitted. The simplest example of this is a sequence of integer (indices). A more sophisticated example of this is a number of (bit-)rows in a hexagonal lattice, each of the bit-rows being limited to a certain length.

In the present application, the term “stream” is used to denote the symbol values at the respective indices of I, which can be associated with points in space, time (or space time). In many applications, one can think of this stream comprising “blocks” of symbols. When the term “codewords” is used in the following, such “blocks” are actually called to be “words.”

Mentioned here are bits being stored or transmitted, but the proposed method equally well applies to ternary or higher order symbols. It is assumed that a addition operation, to be denoted by +, is defined on the symbol alphabet. In the case of bits this will be addition modulo 2. In the case of ternary symbols, this can be addition modulo 3, or addition in a Galois Field or ring, etc. A word is specified by its symbol values in all positions indexed by I. Both the messages and the scrambled messages are examples of words. Next, let y=(y₁,y₂, . . . ,y_{d}) be a string of d bits. Let J={(j(1),j(2), . . . ,j(d)} be an ordered subset of the index set I. y agrees with the word z if for i=1,2, . . . ,d, it holds that yᵢ=zⱼ₍ᵢ₎. Such a subset J specifies either a “portion” of a stream, or “symbol portion” of a stream (in a block). In the most typical practical cases, such portions correspond to some physical “neighborhood.” For a collection X of subsets J of I, each of size d, a word z and a string y=(y₁,y₂, . . . ,y_{d}), f_{X}(y|z) is defined as the fraction of sets J in X for which y agrees with z in J. That is, f_{X}(y|z) measures the fraction of the portions for which the symbol string found in the positions of the portion matches the given string y.

Now, let C be a set of words; C will be referred to as the scrambling code. A set J of symbol positions (indices) is a balanced set for the code C, if and only if all combinations of symbol values occur in J in equally many words from C. Let X be a collection of balanced subsets of size d of I. It can be proved that for each word m and each string y, the average of f_{X}(y|c+m), taken over all scrambling codewords c, equals 1/q^{d}., where q=2 equals the size of the symbol alphabet Q.

As a consequence, let g be a real-valued function defined on Q^{d}, and let G be the function which maps words into (floating point) numbers as G(z)=Σf_{X}(y|z)g(y), where the sum extends over all q^{d} length-d strings y. Then for each word m, the average of G(m+c) over all words from the scrambling code C equals the average of g(y) over all length-d strings. As a consequence, there exists a scrambling codeword such that G(m+c) is at most this average.

The above very general observation is applied for the following special case. For g(y), we take the predicted bit error rate (BER) for a bit whose neighborhood is described by the string y. For X, the set of neighborhoods of all symbol positions is taken. If the scrambling code C is such that the neighborhood of each symbol position is a balanced set for C, then, for each input message m, a scrambling codeword c can be selected such that the predicted BER for m+c is at most the predicted BER for a truly random codeword.

It is then possible to state a main theorem underlying the invention. Fixing a neighborhood set N and a set of bit (symbol) values in the neighborhood y and assuming that for every center position i ∈ I the neighborhood i−N is a balanced set for the set of scrambling codewords (the scrambling code) C, then the average of f(y|c+m) over the scrambling code c ∈ C satisfies the following equation (theorem):

$$\frac{1}{/ C /} {\sum }_{c ∈ C} {f}_{X} ( y / c + m ) = {q}^{- d} .$$

In particular, for the all zeroes stream m, it holds

$${\sum }_{c ∈ C} {f}_{X} ( y / c ) = / C / {q}^{- d} ,$$

which follows, as the definition of f_{X}(y|z) invokes a summation over all portions J in X of c. Hence, the sum of f_{X}(y|z) over all c ∈ C effectuates a double summation that counts how many portions J in any of the scrambling codewords c from C match a given string y, divided by |X|. However, for a given portion J, the number of scrambling codewords c from C that matches y always equals |C|q^{-d} as the portion J is assumed to be a balanced set of C. Now summing this outcome |C|q^{-d} over all J and dividing by |X| confirms our theorem above for the special case wherein m equals the all zeroes stream. The theorem holds for arbitrary streams m.

In the previous paragraph, if m can be any possible stream then, when we consider all possible sums s=c+m, all values of s will occur multiple (viz. |C|) times. Hence, from the value of s, we cannot conclude to the value of c and m, in that case. Hence, the choice of which c is used must be revealed to a receiver in order for unique decodability of m to be possible. As a result, the role of what is called m in the previous paragraph is referred to as the intermediate stream i, in particular in the claims. The lengthening of the stream m to the stream i as proposed according to the invention provides some degree of redundancy that ensures that if s′=c+i is used instead, all possible streams s′ occur at most once. This then allows to uniquely retrieve the values of c and i from the scrambled (mapped) stream s′. The extension from m to i is the role of the extension unit.

A block diagram showing the general layout of an encoding apparatus using guided scrambling is shown in FIG. 5. It comprises an expansion unit 150 for transforming said user data stream m to an intermediate data stream i comprising at least one more symbol than said user data stream m and a first mapping unit 100 comprising a number of mapping elements 101 for mapping different scrambling codewords c of a scrambling code C onto the received intermediate data stream i. The output, i.e. the different mapped user data streams m′ are inputted to a processing unit 200 comprising a number of processing elements 201 for determining the merit values v of a figure of merit (FoM). These merit values v are provided to a selection unit 300 where the optimum merit value vₒₚₜ and, by use thereof, the optimum scrambling codeword cₒₚₜ is selected. In a second mapping unit 400 this optimum scrambling codeword cₒₚₜ is then mapped onto the original user data stream m to obtain the optimum mapped user data stream y which is outputted as channel data stream to the channel, for instance stored on a record carrier 50 or transmitted over a transmission line. Along with the channel data stream y (or incorporated therein) the information about the optimum scrambling codeword cₒₚₜ is also transmitted for use by the decoder.

An embodiment of the processing element 201 of the processing unit 200 is shown in FIG. 6 as an example. It comprises a number of parallel restriction elements 202 for restriction to portions. Such a restriction element e.g. collects a (fixed) number of bits that are stored or transmitted within some spatial of temporal neighborhood of a given bit and translates it into a bit (symbol) string, or integer. To collect the bits (symbols) within a portion into an integer is particularly attractive in a hardware implementation, as it allows the use of such an integer as an address within a memory that comprises a table that stores the figures of merit of all possible values of a portion (i.e. symbol values within a portion). In the most general case, the figure of merit can be different for different portions, hence, FIG. 6 shows multiple tables, where e.g. portion 0 (e.g. at the beginning of a symbol stream) is subject to a different figure of merit than the next portion 1 (e.g. temporally later or spatially advanced within the symbol stream), etc. The collection of all portions is denoted X, hence the last portion is the |X|-1'th portion when numbering from 0.

The output u of these restriction elements is provided to table elements 203 as addresses of the table elements. These address comprise the value of a portion. The table elements comprise the (local) figure of merit of such a portion. All outputs of these table elements 203 are provided to an averaging unit 204 for, e.g., weighted or convex averaging of the (local) figures of merits of the portions into a global figure of merit per stream. As defined in claim 1, the figure of merit of a symbol stream (e.g. a block of symbols) is a sum of figures of merit per portion. With the proper normalization, such a sum becomes an average, as shown in FIG. 6. In general, the choice of the optimum scrambling codeword c_opt is unaffected by the divisioning by such a constant normalization factor, which is hence immaterial. It is evident to somebody skilled in the art, that one can consider more or less slight deviations from taking a sum or average of the per-portion (i.e. local) figure of merit values while still obtaining all the advantages of our invention. Below an example is provided using squares, in which the property is exploited that the squaring operation is a so-called convex(-cup) operation. Hence, when summing or, equivalently, averaging is mentioned, the case of convex averaging as discussed below, and the like is also included.

The invention will now be explained in more detail. According to the invention a code C is applied that satisfies the balanced set condition set in the above equation (theorem). This condition amounts to the requirement that for every position i ∈ I, the neighborhood (i−N) should be a balanced set (i.e. a codeword symbol portion) of the scrambling code C.

A one-dimensional example of the invention will be explained in the following. First, an index set I is considered, the set of all integers 0, 1, . . . ,K−1, where K, K>2, is the stream length, and a set of bits (m₀, m₁, . . . m_{N-1}) on this index set. Further, all ordered subsets J of I of the form (i−N)={i−1,1,i+1}, where i=1, 2, . . . ,K−2, is considered, that is, N={−1,0,1}. The collection of all these ordered subsets J shall be called X. Further, a table g is taken which maps sequences of 3 bits into integer, fixed point or floating point numbers (any table g can be taken). For the sake of concreteness, g is defined as the power (i.e. the square) of a 3-taps filter output:
g(a,b,c)=(0.1*a+0.7*b+0.2*c)²

An example of such a table g could be:

| a | b | c | g(a, b, c) |
|---|---|---|---|
| 0 | 0 | 0 | 0 |
| 0 | 0 | 1 | 0.04 |
| 0 | 1 | 0 | 0.49 |
| 0 | 1 | 1 | 0.81 |
| 1 | 0 | 0 | 0.01 |
| 1 | 0 | 1 | 0.09 |
| 1 | 1 | 0 | 0.64 |
| 1 | 1 | 1 | 1 |

It is obvious that in case the number of table entries would be large, alternatively g could be computed. For a certain user data stream (m₀, m₁, . . . m_{N-1}) the average power G is defined as the average of the local figure-of-merit g over X,

$$G ( {m}_{0} , {m}_{1} , ⋯ , {m}_{N - 1} ) = \frac{1}{K - 2} {\sum }_{i = 1}^{i = K - 2} g ( {m}_{i - 1} , {m}_{i} , {m}_{i + 1} )$$

For lack of knowledge of m₋₁, and m_{N} the average power G does not include the power of the filter outputs nᵢ,
nᵢ=0.1*mᵢ₋₁+0.7*mᵢ+0.2*mᵢ₊₁
at the end points of the index set I (i.e. n₀ and n_{K1}).

Now, the scrambling code is defined. As a first example a repetition code is taken as C. That is, all scrambling codewords (of length K−2, which can be need not be a multiple of 3) shall be of the form
c=(c₀,c₁,c₂,c₀,c₁,c₂,c₀,c₁,c₂, . . . ,c₀,c₁,c₂)
Then, there are in total 2³=8 scrambling codewords each one of them being uniquely specified by a combination of three bits (c₀,c₁,c₂). It can be observed that for any neighborhood (or portion) J=(i−N) in X, the codeword c restricted to J=(i−N) equals y=(cᵢ₋₁,cᵢ,cᵢ₊₁) and that y is some permutation of (c₀,c₁,c₂). Hence, when the average of g over C is considered, the sum over the local figure-of-merit g over all codewords restricted to J is just the average value of g over all length-3 binary sequences, viz. 0.385,

$$\frac{1}{\vert C \vert} {\sum }_{c ∈ C} g ( {c}_{i - 1} , {c}_{i} , {c}_{i + 1} ) = \frac{1}{8} {\sum }_{c 0 = 0 , 1} {\sum }_{c 1 = 0 , 1} {\sum }_{c 2 = 0 , 1} g ( {c}_{i - 1} , {c}_{i} , {c}_{i + 1} ) = \frac{1}{8} ( 3.08 ) = 0.385$$

Here, the fact has been used that in the restriction of all codewords to a subset J, all possible binary sequences of length 3 occur exactly once (each J is a balanced set). (In case, all sub-sequences would occur twice, the same argument would carry through, etc.) When (denoted by “⊕”) a user data bit stream m is added modulo-2 to c, thus obtaining the mapped (or scrambled) stream
m′=m ⊕ c
the result is still a summation over all length-3 binary sequences in the indices comprised by J=i−N, so that the outcome (0.385 in the example) does not change.

This is true, because the addition (modulo-2) of (mᵢ₋₁,mᵢ,mᵢ₊₁) is an invertable operation.

Hence, as already stated, it

$${\overline{g}}_{i} = \frac{1}{\vert C \vert} {\sum }_{c ∈ C} g ( {m}_{i - 1}^{′} , {m}_{i}^{′} , {m}_{i + 1}^{′} ) = 0.385 results that .$$

This means that as mapping operation that combines cᵢ and mᵢ into m′ᵢ any invertable operation on the symbol alphabet can be taken. Next, the average of G(m⊕c) over all scrambling codewords c can be evaluated, as an average of the average g̅ᵢ of g over all scrambling codewords c restricted to some subset J=i−N, over all J in X (that is, over all i, 0<i<K−1). As an average of constant values is also a constant value, it results that the average of G(m⊕c) over all scrambling codewords c is also to the aforementioned constant g̅=0.385, where the fact has been used that the g̅ᵢ do not depend on i.

$$\frac{1}{\vert C \vert} {\sum }_{c ∈ C} G ( m ⊕ c ) = \frac{1}{\vert C \vert \vert X \vert} {\sum }_{c ∈ C} {\sum }_{( i - N ) ∈ X} g ( {( m ⊕ c )}_{i - 1} , {( m ⊕ c )}_{i} , {( m ⊕ c )}_{i + 1} ) = 0.385 .$$

The fact that the average of G(m⊕.) over C equals 0.385, implies that there is at least one codeword c_opt in C for which G(m⊕c_opt) is at most 0.385, that is, there must be a scrambling codeword such that G (the average power of the filter output) of the scrambled (mapped) user data symbol stream is at most 0.385. Alternatively, it could have been concluded that there is at least one scrambling codeword for which G of the scrambled codeword is at least 0.385.

It can be observed that the function g can be allowed to be different for each J, that is in the example above “gᵢ(.,.,.)”. E.g. one can partition the stream of length K, with K even, into two sub-streams of length K/2, with a first function (table) g_{A} in the first sub-stream and a second function (table) g_{B} that applies to the second sub-stream. Then, the average of the global figure of merit function G over the entire stream of length K equals, the fifty-fifty average of the (uniform) average g̅_{A} of g_{A} over all length-3 binary sequences and the (uniform) average g̅_{B} of g₂ over all length-3 binary sequences.

The generator matrix of the code C in the example is as follows.

$$G = [ \begin{matrix}1 & 0 & 0 & 1 & 0 & 0 & & & & 1 & 0 & 0 \\ 0 & 1 & 0 & 0 & 1 & 0 & & ⋯ & & 0 & 1 & 0 \\ 0 & 0 & 1 & 0 & 0 & 1 & & & & 0 & 0 & 1\end{matrix} ]$$

It is evident that when G is restricted to the three columns that correspond to a neighborhood (also generally called symbol portion), any such three neighboring columns are linearly independent.

Further, non-linearities can be introduced in the definition of the scrambling code without affecting the principle of the present invention, e.g.
c=(c₀,c₀c₂⊕c₁,c₂,c₀,c₀c₂⊕c₁,c₂,c₀,c₀c₂⊕c₁,c₂, . . . ,c₀,c₀c₂⊕c₁,c₂)
The addition of an independent linear term “c₁” to the product of bit values “c₀c₂” still ensures that if (c₀,c₁,c₂) are varied over all possible 8 combinations, when the scrambling codeword is restricted to a neighborhood (symbol portion) (in the example: of three successive indices) all possible 8 combinations occur exactly once (hence, all occur equally many times).

Similarly, the linearity of the figure-of-merit G can be distorted e.g. by the introduction of a number of arbitrary contributions (e.g. contributions not dependent on symbol portions, or non-linear combinations of several contributions of several symbol portions etc.) whose number is slight with respect to the total number of terms (K−2 in the example) in G or whose maximum or average overall magnitude distorts G to an extent at which the linear contributions as described here dominate the behavior of G. The benefits of the proposed method still carry through if e.g. the linear average G is replaced by a weighted average, or by a convex average. For instance the square operation is a convex function, and when it is set

$$G ( {m}_{0} , {m}_{1} , ⋯ , {m}_{N - 1} ) = {( \frac{1}{K - 2} {\sum }_{i = 1}^{i = K - 2} g ( {m}_{i - 1} , {m}_{i} , {m}_{i + 1} ) )}^{2}$$

the aforementioned convexity implies that

$$G ( {m}_{0} , {m}_{1} , … , {m}_{N - 1} ) = \frac{1}{K - 2} {\sum }_{i = 1}^{i = K - 2} {( g ( {m}_{i - 1} , {m}_{i} , {m}_{i + 1} ) )}^{2}$$

so that the function G has a linear upper bound for which the squared values of g can be stored in a table instead of the original values g, and the existence of a scrambling codeword that results in a mapped user data word for which G is not larger than typical, follows from application of the present invention to the upper bound (that playes the role of the true G and to which the invention can be applied).

It is clear that the stream length K can be partitioned into any number of parts of not-necessarily equal size and the invention still applies. As a special case, the function (table) gᵢ may be different for all indices i. Furthermore, it is also clear that, if non-uniform, i.e. weighted averages, shall be considered that the weighting function can be included in the function gᵢ.

As a second example of a scrambling code, as scrambling codewords all possible sequences (of length K>3) are considered, generated by the linear feedback shift register shown in FIG. 7. The initial 3-bit contents of the shift register is called the seed. There are 2³=8 possible (binary) seed vectors (of length 3) denoted (c₀,c₁,c₂). An output sequence of the shift register shown in FIG. 7 can be described the linear recursive equation
(i+3=3,4, . . . ,N−1),
cᵢ₊₃=(cᵢ+cᵢ₊₁+cᵢ₊₂)mod 2.
If such a seed (c₀,c₁,c₂) of the feedback shift register is varied over all possible length-3 binary sequences, in any portion J={i−1,i,i+1} all 8 possible length 3 binary strings occur exactly once. Hence, the same reasoning as for the repetition scrambling code carries through as also in this case each J={i−1,i,i+1}, i=1,2, . . . ,K−2, is a balanced set.

It is clear that any table g can be taken. As a variation of the above example, a neighborhood N is defined as not including i:J={i−1,i+1}. Then the number of codewords in the examples above can be halved by setting
c₀+c₁+c₂=0 mod 2,
for instance,
c₁=c₀+c₂ mod 2.
Now functions g (or more generally gᵢ) are considered that have a 2-bit input, corresponding with positions i−1,i+1}. For instance, an additive white Gaussian noise channel L for which the channel output rᵢ is the sum of the channel input aᵢ (e.g. a scrambled user data stream, i.e. aᵢ=m′ᵢ) and a Gaussian noise term “noiseᵢ can be considered:
rᵢ=aᵢ+noiseᵢ
Then the signal-to-noise ratio (SNR), which is the ratio of the average squared value of the channel inputs aᵢ to the average squared “noiseᵢ” value, may depend on aᵢ₋₁ and aᵢ₊₁ (that is, some scrambled user data symbols m′ᵢ₋₁ and m′ᵢ₊₁). Using the well-known Shannon capacity function which expresses that the expected amount of information (fractional number of bits) transmitted about the channel input aᵢ by a channel output rᵢ increases logarithmically with the signal-to-noise ratio (SNR),
Sh(SNR)=log(1+SNR(cᵢ₋₁,cᵢ₊₁))
for each pair (cᵢ₋₁,cᵢ₊₁) and the resulting SNR (as is supposed to be known from characteristics of the channel) the resulting Shannon capacity Sh(cᵢ₋₁, cᵢ₊₁) can be computed. Then, g(cᵢ₋₁,cᵢ₊₁) can be set equal to Sh(cᵢ₋₁,cᵢ₊₁) and the reasoning above can be applied to show that there is always is a scrambling codeword c_opt such that G, i.e. the average of Sh(.,.) over all neighborhoods (i−N) in X (N={−1,1}), is not less than its uniformly average value of g over all length-2 sequences, which equals the uniform average of G over all scrambling codewords. Thus, it can be guaranteed that a minimum effective number of bits is transmitted per stream (on average, in expectation). It is clear that also for this case, the local figure-of-merit g can be allowed to depend on the index i in the lattice I.

In case the signal-to-noise ratio SNR for the i-th transmission (or storage) in the above example also depends on cᵢ₋₂, which is not included in the i-th neighborhood {i−1,i+1}, the signal-to-noise ratio can be minimized (for a given value of the pair of symbol values that is included in the neighborhood (cᵢ₋₁,cᵢ₊₁)) over the symbol value cᵢ₋₂ that this not included in the neighborhood {i−1,i+1}. The result of this minimization is then used as local figure-of-merit g(cᵢ₋₁,cᵢ₊₁). In such a situation, the reasoning as above about G and g, allows one to guarantee a worst case achievable average Shannon capacity. This situation also illustrates the tradeoff between the encoding complexity which grows with the number of scrambling codewords |C|, and the fact that as the subset J are increased in size the guaranteed worst case average result need not be minimized over the influence of additional symbols not included in the original neighborhoods J. E.g. J=(i−N), with N={−2,−1,1}, can be used which doubles the number of codewords to 8, as a single parity check equation to hold for (c₀,c₁,c₂) can no longer be assumed.

In order to illustrate the combination of the guided scrambling technique which is the principal subject of the invention with error control coding, the following shall be considered. The repetition code with 8 scrambling codewords shown above can be understood as the set of multiples over the Galois Field GF(2³) of the all-one vector. Here, the “one” of “all-one” is also to be understood as an element of GF(2³). Error correction codes over GF(2³) exist for which the all-one vector is a codeword. With the term “vector” here, the case that the index set I is more than one dimensional shall not be excluded (the term “array”—although unconventional within the realm of error control coding—would then be more appropriate).

In the case of an additive white Gaussian noise channel with inter symbol interference, the outputs r_{i′} at other positions that i, i′≠i, may also reveal information about the input aᵢ at index i.

The sampling grid of the channel outputs need not coincide with the set of channel input positions. For instance, the channel output may be oversampled so that there are more channel output samples that there are channel input symbols.

In case the channel outputs are binary, the Shannon capacity is simply a combination of entropy terms. For instance, if the inputs are fifty-fifty 0-1 distributed, the Shannon capacity equals 1−h(p_{E}), where p_{E} is the symbol (i.e. bit) error probability and h(.) is the binary entropy function h(x)=−x log 2(x)−(1−x)log 2(1−x). The symbol error probability PE may depend on some neighborhood i−N of a point i in I. In that case, for a scrambling code that satisfies the constraints of the present invention, it follows that there always exists a scrambling codeword c_opt for which the average symbol-wise entropy of the error probabilities is not worse (larger than) than the average of h(p_{E}) over a neighborhood J=(i−N). In case of a dependence on the index i, it is needed to further average over all J in X.

As one of the simplest embodiments of the present invention, as local figure-of-merit g, the symbol error probability (“rate”) p_{E} itself can be considered, as a function of some neighborhood J=(i−N). The dependence on the neighborhood arises through inter symbol interference occurring in the channel, which may be linear or non-linear. Then, when the scrambling code C satisfies the constraints of our invention, there is guaranteed to exist a scrambling codeword c_opt such that the average symbol-wise error probability for a given scrambled user data symbol stream is not worse than the uniform average of the symbol-wise error probability over all subsequences in some J. Again, in case of dependence on which J (e.g. which i in case J is of the form i−N), it is additionally needed to average over all J in X. In the embodiment given before, the binary entropy function h(.) amplifies the contributions for smaller PE relative to contributions of larger PE in comparison with this embodiment.

In case a repetition code is used as scrambling code—which is advantageous due to the simplicity of the code—a “coloring” can be used to construct the code. It must then be true that all indices contained in some subset J of I all have a distinct color.

For the one-dimensional example with the repetition code the coloring is
(0, 1, 2, 0, 1, 2, 0, 1, 2, 0, 1, 2, 0, 1, 2, 0, 1, 2, . . . )
In this example any J in X has three different colors.

For the case of a repetition scrambling code to be designed for use with a hexagonal lattice an embodiment is now presented. Considering a center point and its six neighbors, together constituting a seven element hexagonal cluster, each of the seven elements (symbols or bits) of the cluster (also called user symbol portion) is given a different color (which is equivalent to assigning a different label to each of the seven elements). It can be verified that a hexagonal plane can be tiled with such a set (i.e. partitioned into tiles). A first embodiment thereof is shown in the following table:

| | | | | | | | | | | | | | | | | | | | | | |
|---|---|---|---|---|---|---|---|---|---|---|---|---|---|---|---|---|---|---|---|---|---|
| 0 | | 1 | | 2 | | 3 | | 4 | | 5 | | 6 | | 0 | | 1 | | 2 | | 3 | . . . |
| | 5 | | 6 | | 0 | | 1 | | 2 | | 3 | | 4 | | 5 | | 6 | | 0 | | 1 |
| 2 | | 3 | | 4 | | 5 | | 6 | | 0 | | 1 | | 2 | | 3 | | 4 | | 5 | . . . |
| | 0 | | 1 | | 2 | | 3 | | 4 | | 5 | | 6 | | 0 | | 1 | | 2 | | 3 |
| 4 | | 5 | | 6 | | 0 | | 1 | | 2 | | 3 | | 4 | | 5 | | 6 | | 0 | . . . |

Each different color is symbolized by a different number (label) in this table of which many variations exist. In this particular embodiment of the coloring, the color number increases with two, modulo seven if one goes two rows down. It should be noted that, unlike in a true hexagonal lattice, the vertical and horizontal distances to nearest neighbors are unequal in this table.

The direct way to find the scrambling codeword c_opt is to evaluate the per-stream figure of merit function G for (a subset of) all scrambling codewords. Then, the computational complexity is proportional to the product of the number of scrambling codewords |C| and the stream length K.

An alternative way to find c_opt is to use a number of histograms, one histogram per color, as follows. Then, the computational complexity of counting the histograms is proportional to the stream length. Assuming the stream length is large (e.g. on the order of thousands of bits), the remaining computational complexity is in general negligible. Thus, the computational complexity is reduced by approximately a factor of |C|, the number of scrambling codewords.

A general layout of an encoder using a number of histograms is shown in FIG. 8. While some portions, in particular the selection unit 300 for selecting the optimum merit value vₒₚₜ and generating (or selecting) the optimum scrambling codeword cₒₚₜ, for which here a separate generator unit 301 is provided, and the second mapping unit 400 for mapping the optimum scrambling codeword cₒₚₜ onto the user data stream m, are similar or even identical as shown in FIG. 5, the first part of the encoder is different.

It comprises a counting unit 500 having one or more counting elements for computing a number of histograms H as will be explained below. These histograms H will be provided to a histogram transformation unit 600 having a number of histogram transformation elements 601. As all scrambling codewords are different, herein, each possible choice of a scrambling codeword c effectuates a different transformation of each of the histograms. Hence, there are as many transformations of the set of histograms as there are scrambling codewords (i.e. |C|, in the figure indicated by n=|C|). In the sequel, this is illustrated by means of an example for the one-dimensional case for portions comprising three binary symbols (bits).

An embodiment of the counting unit 500 is shown in more detail in FIG. 9. It comprises a number of parallel restriction elements 501 for restriction to portions. The output u of these restriction elements 501 is provided to one or more counting elements 502 for counting the frequency of occurrence of the values of the portions. The output of these counting elements 502 are the histograms H.

For instance, in the example wherein a portion comprises three subsequent bits from a one-dimensional bit stream, there are 2³=8 possible contents of a portion, viz. the strings 000, 001, 010 . . . , 111. These strings can be identified with the integers 0,1 through 7. In general different portions may overlap (i.e. have symbols positions in common). The collection of all portions X can be split up into a number—3 in this example—of subsets such that the portions within a subset do not overlap. E.g. a first subset of the collection X of portions comprises all portions with indices of the form {i−1,i,i+1}, where is a multiple of 3. A second subset of the collection X comprises all portions of said form for which i is a multiple of 3 plus 1. A third subset of the collection comprises all portions for which i is a multiple of 3 plus 2. It is evident that, as stated for the general case, different portions within the same subset have no indices in common (i.e. have no symbols in common). This is illustrated by means of FIG. 9: per subset of the collection X of portions, a histogram gives the frequency of occurrence of the possible symbol strings within a portion. Such methods cannot just be used in one-dimensional cases, but e.g. also in the case of the hexagonal lattice example discussed in the sequel. In that case, there are A=7 different subset of the collection of all portions, where, the portions within a single subset have no overlap and are uniquely transformed by the choice of a (two-dimensional) repetition codeword.

Now, in FIG. 8, we have that A=3, and three histograms are produced. The first histogram counts how often in the first subset of the collection X each of the 8 possible values 000,001, . . . , 111 occur. The second (third) histogram gives similar counts for the second (third) subset of the collection X. Moreover, it is assumed that a repetition code is used. Through the use of a code as simple as a repetition code, it follows that each of the three types of portions, from the first, second and third subset of the collection are affected in a unique way (i.e. unique per subset) by the choice of a particular scrambling codeword from the repetition code. For each subset of the collection, each choice of a scrambling codeword implies a different transformation of the value of a portions in that subset. As shown in FIG. 8, there are as many transformation units operative on the set of A (3 in the example) histograms as there are scrambling codewords, viz. n=|C|. Hence, in total A|C|(3|C| in the example) individual histograms are transformed. The transformed histograms per subset of the collection are to be summed to a combined histogram over the entire collection. Thus, a transformed set of histograms provides sufficient information to compute the frequency of occurrence of portions (000,001, . . . ,111) in the symbol sequence that is the mapping of the intermediate symbol stream and the particular scrambling codeword onto each other. This presumes that the figure of merit of a portion, e.g. as implemented by means of tables as in FIG. 6, has the same table values for all tables (i.e. the figure of merit is not temporally or spatially varying). Observe that both the definition of a histogram (counting) and the definition of the overall figure of merit in terms of the per-portion figures of merit have in common that they are based on addition (“a sum”). Hence, the sum of the local per-portion figures of merit can be computed when the figure of merit of all possible portions (000,001, . . . ,111) is known and how often each of these portion values occurs in the mapped symbol stream as is given by the summation of the three transformed histograms. Next, the figures of merit can be computed for each possible choice of the scrambling codeword (n=|C| choices), and the optimum codeword c_opt can be selected and used for the final mapping (e.g. addition modulo 2 in case of bitstreams) with the intermediate symbol stream i.

The method of FIG. 5 has a complexity of (|C|K) and the method of FIG. 8 has a complexity of just K. E.g. for a size of the scrambling code of |C| of 2⁷=128 as in the example given for the hexagonal lattice, this constitutes a marked advantage.

In the above, for a collection X of subsets J of I, each of size d, a word z and a string y=(y₁,y₂, . . . ,y_{d}), f_{X}(y|z) have been defined as the fraction of sets J in X for which y agrees with z in J. Assume that J is of the form (i−N), i.e. is a version of some neighborhood N shifted to a central index i. Now, for 1 a color let f_{X}(y|z,1) be the fraction of sets J=i−N in X, where i has color 1, for which y agrees with z in J. It can be observed that if f_{X}(y|z,1) is summed over all colors 1 f_{X}(y|z) is received.

If G(m⊕0)=G(m) shall be evaluated, i.e. for the all-zeroes codeword 0, the knowledge of the set of histograms f_{X}(y|m,1) suffices, as knowledge of the f_{X}(y|m,1) implies knowledge of the f_{X}(y|m). Then, G(m)=Σf_{X}(y|m)g(y) can be computed with an amount of work proportional to the number of y vectors, viz. q^{d}.

It can be observed that with a shift-invariant neighborhood concept, i.e. J=i−N, if it is known that a central index i has color 1, then the colors of the (other) indices in J are also known. Assuming that G(m⊕c) shall be evaluated where c₀=1, c₁=0, c₂=0 and that color 1 corresponds to a bit value in the scrambling codeword of c₁ (“c sub 1”). Then, it is known that for the histogram which has central color 1=0, the central bit is inverted due to the addition of c₀=1 to the message bit at that central index. This addition transforms the histogram f_{X}(y|m⊕c,0)=f(y′|m,0), where y′ and y differ in the bit value that corresponds to the central bit.

Then, it is known that for the histogram which has central color 1=1, the bit to the left of the central bit is inverted due to the addition of c₀=1 to the message bit at that left neighbor. This addition transforms the histogram f_{X}(y|m⊕c,0)=f_{X}(y″|m,0), where y″ and y differ in the bit value that corresponds to the bit left of the central bit (i.e at index i′=i−1, where i is the central index).

Then, it is known that for the histogram which has central color 1=2, the bit to the right of the central bit is inverted due to the addition of c₀=1 to the message bit at that right neighbor. This addition transforms the histogram f_{X}(y|m⊕c,0)=f_{X}(y′″|m,0), where y′″ and y differ in the bit value that corresponds to the bit right of the central bit (i.e at index i′=i+1, where i is the central index).

This way, for the given scrambling codeword, all histograms f_{X}(.|m,1) can be computed by permutations of f_{X}(.|m⊕c,1). It is clear that this holds for any scrambling codeword c, not just for the example codeword given. Then, G(m⊕c)=Σf_{X}(y|m⊕c)g(y) can be computed with an amount of work proportional to the number of y vectors, viz. q^{d}. Per scrambling codeword, the total amount of work to permute the histograms is (at most) proportional to the number of colors times the number of y vectors (viz. q^{d}). When the latter product is smaller than the stream length K, the latter technique saves computational resources with respect to the direct evaluation of G(m⊕c).

FIG. 10 shows part of a channel data stream on a hexagonal lattice where the different colors (or labels) are assigned to the channel symbols according to the above table. Cross hatching symbolizes a first symbol value (e.g. bit value ‘1’) and no hatching symbolizes a second symbol value (e.g. bit value ‘0’) of the channel symbol.

Such a tiling extends the coloring originally defined on the 7-set to the entire hexagonal lattice. Within a set (tile) a single parity check code (i.e. six information bits and one parity bit) is preferably defined. Using the coloring, this code is repeated for every tile, and thus a long repetition code with 2⁶=64 codewords is created. By the use of the single parity check equation, the maximum number of codewords has been reduced of which the figure-of-merit (for a given message m) is to be evaluated from 2⁷ to 2⁶, thus reducing the complexity of encoding. Such a reduction is preferred only when the local figure-of-merit function (g) at a given input position i does not depend essentially on the channel input at position i itself, but only on its neighbors at positions (i−N), where the set of differential neighbor indices N does not contain the zero vector. It should be verified that for this repetition code an arbitrary neighborhood (i−N) contains exactly six differently colored bits and thus is an information set (i.e. a symbol portion). This completes the construction of a code for the above theorem for the two-dimensional code example.

The following paragraph gives a more general treatment of the same histogram based approach to the computations.

In the following an alternative method of evaluating f(y|m+c) which needs a summation over I once (preprocessing step) and manipulates histograms for each c shall be explained. It shall be assumed that the scrambling code has been constructed using a lattice coloring based on a tiling as described above. The set of colors (labels) shall be denoted by U. The index set I of the lattice of channel inputs and outputs can then be partitioned into disjoint subsets Iᵤ, u ∈ U. For each u ∈ U the empirical fractions fᵤ(y|s), s=m+c , are defined by
fᵤ(y|s)=1/n|{i∈ Iᵤ| for all j ∈ N, yⱼ=sᵢ₋ⱼ}|,
where n is the size of I. The previously defined empirical fractions can be computed from the new empirical fractions by means of a simple summation over all colors,
f(y|s)=Σ_{u∈U} fᵤ(y|s).
The scrambling code has the property that for any scrambling codeword, lattice points of equal color (i.e. equal label) carry the same codeword symbol value. Now, when j ∈ N, the definition of the tiling implies for fixed index in the neighborhood set j∈N that all points from {i−j/i ∈ Iᵤ have equal color (label). As C is constant on points with equal color, there is a symbol value zⱼ(u, c) such that for each i ∈ Iᵤ it holds
c_{i-Δj}=zⱼ(u, c).
As a consequence, it holds
fᵤ(y|m+c)=1/n|{i∈ Iᵤ| for all j ∈ N, mᵢ₋ⱼ=yⱼ−zⱼ(u, c)}|.
As a consequence, if it is denoted (z₁(u, c), z₂(u, c), . . . , zₙ(u, c)) by z(u, c), it holds
fᵤ(y|m+c)=fᵤ(y−z(u, c)|m)
This equation can be used as follows. First, given the message m that shall be scrambled, for all colors u and all q-ary vectors of length a the quantity fᵤ(y/m) is calculated. This involves a summation over all lattice points. Subsequently, for each color u and each code c ∈ C, fᵤ(y|m+c) is calculated using the above equation. It should be noted that the j-th entry of zⱼ(u, c) equals the value of c in position i−Δj for any i ∈ Iᵤ.

As a repetition construction is used, if an error correcting code over GF(2⁷) were used, when gathering bits with different colors in one symbol, the proposed scrambling code would consist of the all ones codeword multiplied with an arbitrary factor from GF(2⁷). For GF(2¹⁴) two tiles could be grouped into a symbol. In case seven and its multiples are not desired as a symbol dimension, the construction of the coloring given in the above table can be extended by repeating on a single row e.g. the numbers from 0, 1, . . . , 7 and use GF(2⁸).

The following presents an 8-coloring that has more favorable properties when it comes to combining the proposed guided scrambling technique with error control codes that operate on 8-bits bytes, as is common practice

| | | | | | | | | | | | | | | | | | | | | | |
|---|---|---|---|---|---|---|---|---|---|---|---|---|---|---|---|---|---|---|---|---|---|
| 0 | | 1 | | 2 | | 3 | | 4 | | 5 | | 6 | | 7 | | 0 | | 1 | | 2 | . . . |
| | 6 | | 7 | | 0 | | 1 | | 2 | | 3 | | 4 | | 5 | | 6 | | 7 | | 0 |
| 3 | | 4 | | 5 | | 6 | | 7 | | 0 | | 1 | | 2 | | 3 | | 4 | | 5 | . . . |
| | 1 | | 2 | | 3 | | 4 | | 5 | | 6 | | 7 | | 0 | | 1 | | 2 | | 3 |
| 6 | | 7 | | 0 | | 1 | | 2 | | 3 | | 4 | | 5 | | 6 | | 7 | | 0 | . . . |
| | 4 | | 5 | | 6 | | 7 | | 0 | | 1 | | 2 | | 3 | | 4 | | 5 | | 6 |

This 8-coloring of the hexagonal lattice has very favorable properties that suit combination with error control coding which will be explained below. It shall be remarked that with respect to the choice of the scrambling codeword length, the most logical choice is to make that (approximate) overlap with the stream size of the first error correcting code that is decoded after the optical storage channel. Then, the proposed guided scrambling technique limits the predicted number of bit errors in that stream to a “typical” expected value for “truly” (i.e. uniformly) random input data.

The mapping of the different scrambling codewords onto the user data stream is illustrated in FIG. 11 (for the two-dimensional case) and in FIG. 12 (for the one-dimensional case). In FIG. 11 part of the two-dimensional strip S of user data is shown, which is already labeled as shown in FIG. 10. Indicated by U is a user symbol portion which, in this example, comprises a central symbol b0 and six nearest neighboring symbols b1-b6 surrounding the central symbol b0. On the left hand side the different codeword symbol portions cu₀-cu_{N-1} of different scrambling codewords c are given which are now mapped over the labeled user data. A scrambling codeword c comprises of a number of identical codeword symbol portions cu, each codeword symbol portion having a fixed number of codeword symbols. To explain the mapping in more detail it shall be assumed that, for instance, the central bit b0 is labeled with a first label 10 and the surrounding bits b1-b6 are labeled with labels 11-16.

In the first iteration of the mapping step the first codeword symbol portion c₀ shall be mapped onto all user symbol portions U of the strip S. Thus, for instance, the first codeword symbol cu₀₀(=0) of the first codeword symbol portion cu₀ is mapped over all labels 10 present in the strip S. Thereafter, all other codeword symbols cu₀₁-cu₀₆ of the first codeword symbol portion cu₀ are mapped over the corresponding labels 11-16 present in the strip S. In the first iteration, the bit-string “0000000” is thus assigned to all user symbol portions U.

In further iterations the other codewords symbol portion cu₁-cu_{N-1} are mapped onto the user data stream in the same way, e.g. in the second iteration the first codeword symbol cu₁₀(=1) is mapped over all labels 10 etc., so that the bit-string “0000001” is assigned to all user symbol portions U.

In each iteration the codeword symbols of the mapped symbol codeword symbol portion are then added (in the binary case modulo 2; in the M-ary case modulo M) to the underlying user symbol value. Thereafter, in each iteration the merit value of a figure of merit (FoM) is determined.

In FIG. 12 part of a one-dimensional user data stream is shown where each user symbol portion comprises 5 subsequent symbols. As explained for the two-dimensional case shown in FIG. 11, the different codeword symbol portion cu₀-cu_{N-1} of different scrambling codewords c are separately mapped onto all user symbol portions U of the user data stream which has been labeled before by five different labels 10-14. The BER is only know after bit-detection and not in the encoder. Thus, when using the term “BER”, a prediction for the BER using some channel model is meant. Such a prediction of a bit error event at position i in the lattice index set I depends on the neighboring positions i−N={i−n|n∈N}. In the computation of the bit error probability at a location i, the symbol values of the positions outside i−N may be chosen arbitrarily (e.g. all zeroes), or may be varied over a number of possible combinations to find the “worst case” of this predicted BER over the bit positions not included in the model.

The task of the guided scrambler is to find a “good” scrambling codeword c*, c*=arg min_{c∈C}BER(m+c).

The guided scrambler is thus an encoder, as the addition of the scrambling codeword c* to the input array (“message” or “user data stream”) can be seen as an encoding operation. For the sake of completeness, it shall be mentioned that the input data of the guided scrambler may actually be the output of other encoding operations. For the sake of generality, it shall be further mentioned that the number of codewords that need to be considered can be reduced to a subset S ⊂ C

$$\frac{1}{/ S /} {\sum }_{c ∈ S} BER ( c + m ) \leq \frac{1}{/ S /} {\sum }_{c ∈ C} BER ( c + m ) = \frac{1}{α} \frac{1}{/ C /} {\sum }_{c ∈ C} BER ( c + m ) , \\ where α = \frac{/ S /}{/ C /} .$$

Therefore, there exists a codeword c′∈ S, such that

$$BER ( m + {c}^{′} ) \leq \frac{1}{/ S /} {\sum }_{c ∈ S} BER ( m + c ) \leq \frac{1}{α} \frac{1}{/ C /} {\sum }_{c ∈ C} BER ( m + c ) .$$

In words, it can be seen that if only the minimum of BER(c+m) over a subset S is searched which contains a fraction α<1 of the scrambling code C, this costs at most an increase 1/α of the guaranteed predicted bit error rate. As a consequence, if m is not changed, i.e., restrict the search to the subset S consisting of the all-zero word only, the BER is at most a fraction 1/α=64 times as large as the average BER over the entire code.

As already stated, a straightforward implementation of the guided scrambling search would evaluate BER(m+c) for all possible scrambling codewords c, and pick that codeword c* for which BER(m+c*) is minimal. A straightforward evaluation of BER(m+c) for a candidate scrambling codeword c entails the evaluation of f(y/m+c) for all y. For each candidate scrambling codeword c, a summation over the entire lattice index set I is involved, which has a size equal to the codeword length K.

It is clear that the order in which the quality of the codewords from C are tested is irrelevant. One might benefit from this by ordering the words from C in such a way that is relatively simple to obtain the vectors z(u, c) for the codeword c under consideration from the vectors z(u, d) from the codeword d just considered (a Gray-code like manner).

As described above, the worst case BER can be made not to exceed the average case BER by selecting, for each possible information string, a suitable encoding alternative. In the following it shall be explained how to combine this with error correcting codes.

To see the problem, it shall be assumed that a message string m is encoded into a word d(m) from an error-correcting code D. To the word d(m), a suitable word from the scrambling code C is added, say the word c(d(m)), so that eventually the word d(m)+c(d(m)) will be outputted to the channel, e.g. written on the medium. As a consequence, if M denotes the set of all possible strings that can be encoded, the set of words that can be recorded equals
X={d(m)+c(d(m))|m ∈ M}

The problem is that the error control capabilities of X may be significantly worse than those of D.

It is ensured that the set X has good error-control capabilities by ensuring that C and D are contained in a powerful linear error-correcting code E, and that C and D only have the all-zero word in common. As in this case X is contained in E, any decoding algorithm for E for retrieving d(m)+c(d(m)) can be used, and from this m can be retrieved. A more or less explicit example is given for the case of a two-dimensional code. This example in fact demonstrates the combination of a scrambling code and an error-correcting using the so-called lambda-trick as described in U.S. Pat. No. 5,671,236 and U.S. Pat. No. 5,845,810.

Let E be an [n k] code, whose symbols are 8-bits bytes. That is, a word from E consists of n bytes or, equivalently, it consists of 8n bits. It is assumed that E contains the word consisting of ones only. Then, by linearity, for each byte x, E contains the word consisting of an n-fold repetition of x.

The code C ⊂ E consists of 64 words, each containing n bytes. It is described as follows: bits of equal color have the same value; the number of colors from {0, 1, 2, 3} for which the bit is set to “1” is even, as is the number of colors from {4, 5, 6, 7} for which the bit is set to “1”. In other words, C consists of all words of the form (x, x, . . . , x) where x=(x₀, x₁, . . . ,x₇) such that
x₀+x₁+x₂+x₃≡0 (mod 2), and x₄+x₅+x₆+x₇≡0 (mod 2).

Now, the coloring of the hexagonal lattice with 8 colors the above table shall be considered. For i=0, 1, . . . , 7 the colors of the neighborhood of a point colored with color i is as follows (where color indices are to be read modulo 8):

| | | |
|---|---|---|
| i + 2 | i + 3 | |
| i + 7 | (i) | i + 1 |
| i + 5 | i + 6 | |

It can be seen that the six points of each neighborhood are colored with distinct colors. The two missing colors in the neighborhood of a point colored with i are i and i+4. As a consequence, the six points from any neighborhood are colored with three colors from {0, 1, 2, 3} and three colors from {4, 5, 6, 7}. Combining this observation with the definition of C, it can be seen that in any neighborhood, each of the 2⁶ possible bit-combinations occurs once amongst the words from C. For completeness, it shall be mentioned that restrictions on x similar to those described above also yield a suitable code C. In fact, for any a ∈ {0, 1} and any b ∈ {0, 1}, let C_{a,b} be the code consisting of all words of the form (x, x, . . . , x) where x=(x₀,x₁, . . . , x₇) is such that
x₀+x₁+x₂+x₃≡a (mod 2), and x₄+x₅+x₆+x₇≡b (mod 2).
It is easy to see that for any a and b, C_{a,b} is a code that is suitable for the desired purposes.

Now, encoding shall be described by use of the simple flow-chart shown in FIG. 13. Let G be a generator matrix for E that only has ones in its top row. A string m consisting of k−1 bytes will be encoded into a string of n bytes. Encoding consists of two steps.
S11: Encode m to the codeword d(m)=(0, m)G
S12: For a suitably chosen byte x=(x₀,x₁, . . . ,x₇) for which the number of ones in both x₀, x₁, x₂, x₃ and x₄, x₅, x₆, x₇ is even, m is encoded to d(m)+(x, x, . . . , x). It should be noted that m is encoded into a word from the code E.

Decoding, which is illustrated in the simple flow-chart of FIG. 14, can readily be done with a decoder for E. It shall be assumed that the word after ECC decoding the received channel word r (step S21) equals w=(w₁,w₂, . . . ,wₙ). Then the decoded message m is found from the equation
w=(w₁,w₁, . . . ,w₁)+(0,m)G
by a separation step (S22) and a demapping step (S23). If G contains an identity matrix, as commonly is the case, m simply equals the series of bytes in the positions corresponding to the identity matrix.

FIG. 15 shows a block diagram of a decoder according to the invention. This figure also illustrates the separation and demapping step for the case of a (n,k+1) ECC code (codeword length n, dimension k+1), which is systematic in its leftmost k+1 positions. The choice of the scrambling codeword is revealed through the leftmost information symbol. The message m consists of the subsequent k information symbols. One output of the separation unit 800, viz. (w₁, w₁, . . . , w₁), represents the scrambling codeword (from a repetition code C). The other output of the separation unit 800 is the intermediate sequence i, viz. (0,w₂−w₁, . . . ,wₙ−w₁) and results from subtracting the scrambling codeword (w₁, w₁, . . . , w₁) from the output (w₁,w₂, . . . ,wₙ) of the ECC decoder 700. Finally, the demapping unit 900 merely removes the leftmost symbol from the intermediate sequence i, as well as the ECC parity symbols, in order to obtain the message symbol sequence m of length k.

In order that this method can be applied, it is required that the code E contains the all-one word. This is true if E is a Reed-Solomon codes over F_{q} of length K=q−1, but is not true for Reed-Solomon codes of length K smaller than q−1. By a minor modification, an [n, k] shortened Reed-Solomon code E can be transformed into a code that contains the all-one word. Indeed, let a=(a₁,a₂, . . . ,aₙ) be a word from E such that for i=1, 2, . . . , n, aᵢ≠0, which always exists. Now, the generalized Reed-Solomon code Eₐ shall be denoted by Ea={(c₁/a₁, c₂/a₂, . . . , cₙ/aₙ)/(c₁,c₂, . . . cₙ) ∈ E}. As E contains a, the all-one word is in Eₐ. Two rather obvious methods exist for encoding a string of information bytes to a word in Eₐ, assuming that of an encoder Ψ for E is disposed.

A first alternative is to feed the information string to Ψ, followed by dividing the i-th symbol by aᵢ. For the second alternative, it is assumed that Ψ is a systematic encoder. The information symbol corresponding to position i can be multiplied with aᵢ, and the modified information stream can be fed to Ψ. The parity symbols produced by Ψ are divided by aⱼ for the appropriate values of j; the information symbols are written down unaltered, i.e., without multiplication with aᵢ's.

Obviously, the manner of encoding must be known to the decoder. Decoding to Eₐ can be done by first multiplying the i-th symbol of the received word with aᵢ, and subsequently applying a decoder for E. By dividing the i-th symbol of the obtained word from E by aᵢ, the corresponding word in Eₐ is obtained. If one is interested in the information symbols only, and encoding was done in a systematic way, no divisions need to be made.

If the center bit should be included in the neighborhood as well, a simple modification from the results of the above described method can be used. It is proposed to use as scrambling code the set of all words of the form (x, x, . . . , x), where x=(x₀, x₁, . . . , x₇) contains an even number of bits set to “1”. As any 7 positions in the [8, 7, 2] code form a balanced set, and all bits in a neighborhood (including the central bit) have different colors, the above theorem can still be applied. It should be noted that in this case, C consists of 2⁷=128 words.

Using this so-called lambda-trick of Denissen and Tolhuizen as described in U.S. Pat. No. 5,671,236 and U.S. Pat. No. 5,854,810 the scrambling method can efficiently be combined with a byte-oriented error correcting code that contains the all-one word. A simple modification of Reed-Solomon codes is proposed that forces the all-one word to be in the modified code. The fact that the proposed scrambling code of the invention can be considered as multiples of an all one codeword can facilitate the use of the “lambda-trick”. Regarding further details of this “lambda-trick” reference is made to the above mentioned US patents U.S. Pat. No. 5,671,236 and U.S. Pat. No. 5,854,810 which are herein incorporated by reference.

By use of FIG. 16 the use of the lambda-trick can be illustrated. An error-control code C′ is considered that has the scrambling code C as a subcode; that is, each word of C is a word from C′. The code C′ is partitioned into m=|C′|/|C| sets, say A₁,A₂, . . . ,Aₘ, each containing |C| words (here, |A| denotes the number of elements of the set A). In FIG. 16 each such set is depicted as a block of |C| rows. The number of messages that can be encoded equals m. For each message, there is an index j such that the encoder encodes this message to a word from Aⱼ, i.e. the message is determined by the block in which its encoded version resides. The encoder chooses which codeword to pick in Aⱼ in order to optimize an objective function.

It is obvious to someone skilled in the art that the same principle applies when C is an arbitrary coset of a subcode of C′.

The decoder first decodes the received word to a codeword c from C′. It then finds the index j such that c is in Aⱼ. In a “demapping” step, the transmitted message is retrieved from j.

In a preferred embodiment, each Aⱼ is a coset of C. That is, for each j, there exists a codeword cⱼ such that each word from Aⱼ is of the form cⱼ+c from some scrambling word c; in other words, Aⱼ={cⱼ+c|c∈ C}. This preferred embodiment allows the encoder to determine efficiently the coset corresponding to a given message (as explained above). It also allows the decoder to demap a codeword to the encoded message in a simple way.

As mentioned above, it is proposed that C′ has C as a subcode. In this preferred embodiment, the repetition code for C is chosed. However, not each Reed-Solomon codes C′ contain the repetition code. A minor modification of the conventional Reed-Solomon codes (as described above) results in codes C″ that enjoy all of virtues Reed-Solomon codes (equal error correcting capability, virtually the same encoding and decoding operations) but do contain the repetition code.

To conclude, the proposed invention assumes that the bit error probability of a storage or transmission channel at a given point (in time and/or space) can be expressed as a function of a the channel inputs in a neighborhood of the given point and of the channel input at the point itself. Furthermore, it is assumed that the expected bit error rate over all channel outputs in a given stream can be expressed as an average of the given function over the stream. The proposed scrambling method involves the modulo q (binary: q=2) addition of a scrambling codeword suitably chosen from a small scrambling code C, which is also called guided scrambling. As already stated, instead of the (predicted) bit error rate (average of the predicted bit error probabilities for the symbols), the present invention can likewise be applied to other functions that can be expressed as or approximated as an average of local functions, where these local functions depend only on the neighborhood positions of a given lattice position. An example of such an alternative figure of merit would be the power (i.e. squared value) after a simple linear filtering operation, i.e. the output power of a filter.

According to the invention a sufficient condition on the scrambling code C is provided, such that there always exists a scrambling codeword c* such that with c* added to the message, the predicted bit error rate will never exceed its expected value for uniformly random inputs.

Using the proposed tiling of the channel data stream scrambling codes C can be constructed that satisfy the afore-mentioned condition for the two-dimensional channel as used in the two-dimensional optical storage, that have only a small number of codewords to be searched through. A number of ways have been indicated to combine the proposed guided scrambling method with error correcting codes. Out of the possibilities that are indicated the use of the lambda-trick is a preferred approach.

The use of the encoding method according to the invention is also detectable from the output signal of the channel data stream recorded on a record carrier or transmitted as a signal via a transmission line. For a normal record carrier, the probability that the first symbol of channel data stream matches the output of an encoder is there, but is small. In practice, a stream consists of thousands or millions of successive blocks each comprising a codeword. The probability that for e.g. a fraction of 99% of these blocks (never 100% due to channel errors on the recording medium) or more, the value of the first symbol of a codeword (or in general, the choice of c_opt, out of all possible scrambling codewords from C) found on the recoding medium matches the first symbol of a noiseless codeword produced by an encoder according to the invention vanished, i.e. there cannot be a coincidence, because of the large number of blocks, typically found in any recording application. A typical block length (i.e. codeword length) is order of magnitude “thousands of bytes”. A typical recording medium contains Gigabytes or more. In summary, for a recording medium not in line with the present invention, it will not be possible to construe an encoder in the invention, such that when the encoder is fed with the user data stream stored on the recording medium the corresponding choice for the scrambling codeword would match the choice of the scrambling codewords that can be detected on the recording medium with a likelihood that exceeds chance.

Thus, in order to detect the use of the encoding method according to the invention, the following steps can be applied:

(1) Retrieve the encoded data streams (thousands of blocks per disc), and

(2) Re-encode the data streams according to the method according to the invention.

If these re-encoded data streams “often” agree with the streams as recorded on disc, the likelihood that the encoding method according has been used is almost 1.

It follows a list of further embodiments of the invention. In these embodiments, the expansion unit has been trivialized to a point where it is absent, and the choice which scrambling codeword is used must be communicated to the receiver by separate means.

In an embodiment of the encoding apparatus for encoding a user data symbol stream (m) into a channel symbol data stream (b), by means of a set C of scrambling codeword symbol streams (c), where a symbol stream is an ordered set of symbol values defined on a set of symbol input positions I, using a collection X of subsets J of I and a i.e per-stream (global) figure of merit function (G)

at least one codeword contains at least two different symbol values,

the subsets J are balanced subsets of C,

the per-stream figure of merit function G is a linear combination of values of a local figure of merit function (table) g of symbol values evaluated on all subsets J (from X), said encoding apparatus comprising

a processing unit for determining the value (v) of the per-stream figure of merit function (G) of the outcome of mapping a codeword (c′) onto said user data symbol stream (m).

a selection unit for selecting the optimum per-stream merit value (v_opt) from said per-stream merit values (v) of said mappings of codewords (c′) on to the user data stream (m′) and for using said optimum merit value (v_opt) for selecting the corresponding optimum scrambling codeword (c_opt),

a mapping unit (a.k.a. scrambling unit) for obtaining a mapped user data stream (m′_opt), that results from mapping the optimum codeword (c_opt) onto the user data stream (m), to serve as input symbol stream (b) to a (noisy) channel (L).

This embodiment can be further improved in that

the set of input positions (I) has a lattice structure,

the collection (X) is a collection of ordered sets of neighboring positions (i−N) of (a subset of) the set of all input positions (i in I),

the code (C) is a coset of a linear code,

the size of the code (C) is at least 4.

A further embodiment is improved in that the scrambling code (C) is cyclic in at least one dimension.

The encoding apparatus is further improved in that the scrambling code (C) is a repetition code of a certain dimension (k),

the index set (I) is partitioned into a number (U) of subsets (Iᵤ), where the dimension of the code (k) is at most equal to the number of subsets (U),

for all subsets (J) in the collection (X), different indices (i) in a set (J) all are contained in a distinct subset (I_{u′}) of I.

A balanced subset of input positions (J) with a certain size (j) from an index set (I) for a non-empty code (C) can be used with the encoding apparatus where the restriction of the scrambling codewords (c) from the scrambling code (C) to the subset of indices (J), all possible sequences of length (j) equal to the size of the balanced subset (J), occur equally many times.

The encoding apparatus can be further refined in that the local figure-of-merit function (g) of an ordered subset of symbol values (y) on a subset (i−N) is an function of the estimated amount of information (P) revealed by the channel (L) about the channel input at index (i) by the aforementioned ordered subset of channel input symbols (y) and wherein said optimum merit value (v_opt) is the maximum merit value.

A further improvement is that the estimated amount of information (P) revelead by the channel is the expected symbol error rate at index (i).

A further improvement can be achieved in that the local figure-of-merit function (g) is the output power of a filter at an output index (i) given an ordered subset of filter input symbols in a neighborhood (i−N).

To improve the encoder the estimated amount of information (P) revealed by the channel (L) about the channel input at index (i) by the ordered subset of channel input symbols (y) on a subset (i−N) is minimized over the values of symbols at indices (i′) not in the subset (i−N).

To improve the encoder the processing unit for determining the value (v) of the per-stream figure of merit function (G) of the outcome of mapping a codeword (c′) onto said user data symbol stream (m) uses a set of histograms.

To improve the encoder the scrambling code (C) is a subcode of an error control code (C′) with which the user data symbol streams (m) are encoded.

1. Encoding apparatus for encoding a user data stream (m) into a channel data stream (y), comprising:
an expansion unit (150) for transforming said user data stream (m) to an intermediate data stream (i) comprising at least one more symbol than said user data stream (m),
a processing unit (100, 200, 500, 600) for iteratively determining for each scrambling stream (c) from a scrambling code (C) the value (v) of a figure of merit for the scrambling stream (c) using said intermediate data stream (i), a scrambling stream (c) comprising equally many symbols as said intermediate data stream (i), wherein said figure of merit is a sum over a collection of portions of said scrambling stream (c), said portions comprising at least two symbol positions from said scrambling stream, each term of the sum being a figure of merit for said portion of the scrambling stream (c) using the corresponding portion of said intermediate stream (i), and in each of said portions of the scrambling stream (c) each possible combination of symbols occurs in equally many scrambling streams (c) from said scrambling code (C),
a selection unit (300) for selecting an optimum merit value (v_opt) from said merit values (v) and for selecting an optimum scrambling stream (c_opt) for which the figure of merit equals said optimum merit value (v_opt), and
at least one mapping unit (400) for mapping the symbols of said optimum scrambling stream (c_opt) onto the corresponding symbols of said intermediate data stream (i) to obtain said channel data stream (y) for output to a channel.

2. Encoding apparatus as claimed in claim 1,
wherein said at least one mapping unit (400) is operative for mapping symbols of a scrambling stream (c) onto the corresponding symbols of said intermediate data stream (i) and wherein said processing unit is operative for determining for each scrambling stream (c) the merit value (v) of said figure of merit by using the result from said mapping of the symbols of said scrambling stream (c) onto the corresponding symbols of said intermediate data stream (i).

3. Encoding apparatus as claimed in claim 1,
wherein said at least one mapping unit (400) comprises means for mapping symbols of a scrambling stream (c) onto the corresponding symbols of the intermediate data stream (i) by adding said symbols of said scrambling stream (c) to the corresponding symbols of the intermediate data stream (i).

4. Encoding apparatus as claimed in claim 1,
wherein said scrambling code (C) is a repetition code.

5. Encoding apparatus as claimed in claim 4,
wherein said processing means (600) is operative for determining the sum of the merit values (v) for the portions of the channel data stream from at least two histograms (H), where each histogram stores frequencies of occurrence of combinations of symbols in a number of said portions of said intermediate data stream (i).

6. Encoding apparatus as claimed in claim 1,
wherein said channel data stream is a one-dimensional data stream and said portions each comprise a fixed number of subsequent symbols, in particular in the range from 3 to 8 bits.

7. Encoding apparatus as claimed in claim 1,
wherein said channel data stream is a two-dimensional data stream, said channel data evolving in a first direction along a strip of infinite extent of a two-dimensional lattice and of finite extent in a second direction substantially orthogonal to said first direction, said strip comprising a number of symbol rows stacked upon each other along said second direction, and wherein said portions each comprise a fixed number of symbols.

8. Encoding apparatus as claimed in claim 7,
wherein said symbols are arranged on the lattice points of a quasi-square lattice, a quasi-rectangular or a hexagonal lattice.

9. Encoding apparatus as claimed in claim 8,
wherein said portions each comprise seven symbols arranged on the lattice points of a hexagonal lattice, each user portion comprising a central user symbol and six nearest neighboring symbols.

10. Encoding apparatus as claimed in claim 1,
wherein said expansion unit is operative for transforming said user data stream (m) to said intermediate data stream (i) by appending at least one symbol to said user data stream (m), wherein the value of said at least one symbol is known to the encoder and decoder and is the same for all possible user data streams.

11. Encoding apparatus as claimed in claim 1,
wherein said expansion unit is operative for transforming said user data stream (m) to an intermediate stream (i) that is a word from an error correction code (C′), the scrambling code (C) being a coset of a subcode of said error correction code (C′) and the result of mapping a scrambling stream (c) from said scrambling code (C) onto said intermediate stream (i) being a word from said error correction code (C′).

12. Encoding method for encoding a user data stream (m) into a channel data stream (y), comprising the steps of:
transforming said user data stream (m) to an intermediate data stream (i) comprising at least one more symbol than said user data stream (m),
iteratively determining for each scrambling stream (c) from a scrambling code (C) the value (v) of a figure of merit for the scrambling stream (c) using said intermediate data stream (i), a scrambling stream (c) comprising equally many symbols as said intermediate data stream (i), wherein said figure of merit is a sum over a collection of portions of said scrambling stream (c), said portions comprising at least two symbol positions from said scrambling stream, each term of the sum being a figure of merit for said portion of the scrambling stream (c) using the corresponding portion of said intermediate stream (i), and in each of said portions of the scrambling stream (c) each possible combination of symbols occurs in equally many scrambling streams (c) from said scrambling code (C),
selecting an optimum merit value (v_opt) from said merit values (v) and an optimum scrambling stream (c_opt) for which the figure of merit equals said optimum merit value (v_opt), and
mapping the symbols of said optimum scrambling stream (c_opt) onto the corresponding symbols of said intermediate data stream (i) to obtain said channel data stream (y) for output to a channel.

13. Decoding apparatus for decoding a channel data stream (r) into which a user data stream (m) is encoded according to a method of claim 11, comprising:
an ECC decoding unit (700) for decoding said channel data stream (r) to a channel codeword (y) of said error correction code (C′),
a separation unit (800) for finding an intermediate data stream (i) and a scrambling codeword (c) from said channel codeword (y) such that mapping said scrambling codeword (c) onto said intermediate data stream (i) results in said channel codeword (y), and
a demapping unit (900) for retrieving a user data stream (m) from said intermediate data stream (i) such that expanding said user data stream (m) to an intermediate data stream comprising at least one more symbol than said user data stream (m) results in said intermediate data stream (i).

14. Decoding method for decoding a channel data stream (r) into which a user data stream (m) is encoded according to a method of claim 11, comprising the steps of:
decoding said channel data stream (r) to a channel codeword (y) of said error correction code (C′),
finding an intermediate data stream (i) and a scrambling codeword (c) from said channel codeword (y) such that mapping said scrambling codeword (c) onto said intermediate data stream (i) results in said channel codeword (y), and
retrieving a user data stream (m) from said intermediate data stream (i) such that expanding said user data stream (m) to an intermediate data stream comprising at least one more symbol than said user data stream (m) results in said intermediate data stream (i).

15. Record carrier storing a channel data stream (r) into which a user data stream (m) is encoded according to the encoding method as claimed in claim 1.

16. Signal carrying a channel data stream (r) into which a user data stream (m) is encoded according to the encoding method as claimed in claim 1.

17. Computer program comprising program code means for causing a computer to carry out the steps of the method as claimed in claims 12 or 14 when said computer program is run on a computer. Encoding and decoding apparatus and corresponding methods
